(19) United States
(12) Patent Application Publication
(10) Pub. No.: US 2025/0035680 A1
(43) Pub. Date: Jan. 30, 2025

(54) METHODS AND MECHANISMS TO IMPROVE MONITORING CAPABILITIES USING RATE OF CHANGE OF SENSOR VALUES

(71) Applicant: Applied Materials, Inc., Santa Clara, CA (US)

(72) Inventors: Suketu Parikh, San Jose, CA (US); Jimmy Iskandar, Fremont, CA (US); Tsz Keung Cheung, San Jose, CA (US); Chih Wei Lin, Hsinchu City (TW); Michael D. Armacost, San Jose, CA (US)

(21) Appl. No.: 18/226,554

(22) Filed: Jul. 26, 2023

(51) Int. Cl. G01R 19/12; H01L 21/66

(52) U.S. Cl. CPC G01R 19/12; H01L 22/10

(57) ABSTRACT

An electronic device manufacturing system configured to obtain current sensor data associated with a sensor of a substrate manufacturing system and determine a slope value associated with the current sensor data. Responsive to determining that the slope value satisfied a threshold criterion associated with a fault detection limit, at least one of an alert is generated or a corrective action performed.

### TECHNICAL FIELD

The present disclosure relates to electrical components, and, more particularly, to methods and mechanisms for monitoring capabilities by using the rate of change of sensor values.

### BACKGROUND

Manufacturing of modern materials often involves various deposition techniques, such as chemical vapor deposition (CVD) or physical vapor deposition (PVD) techniques, in which atoms or molecules of one or more selected types are deposited on a semiconductor device (e.g., a substrate) held in low or high vacuum environments that are provided by vacuum processing (e.g., deposition, etching, etc.) chambers. Materials manufactured in this manner can include monocrystals, semiconductor films, fine coatings, and numerous other substances used in practical applications, such as electronic device manufacturing. Many of these applications depend on the purity and specifications of the materials grown in the processing chambers. The quality of such materials, in turn, depend on adherence of the manufacturing operations to correct process specifications. To maintain isolation of the inter-chamber environment and to minimize exposure of substrates to ambient atmosphere and contaminants, various sensor detection techniques are used to monitor processing chamber environment, substrate transportation, physical and chemical properties of the products, and the like to detect potential anomalies and issues. Improving precision, reliability, and efficiency of such monitoring presents a number of technological challenges whose successful resolution facilitates continuing progress of electronic device manufacturing and helps to meet the constantly increasing demands to the quality of the products of semiconductor device manufacturing.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In an aspect of the disclosure, an electronic device manufacturing system is configured to obtain current sensor data associated with a sensor of a substrate manufacturing system and determine a slope value associated with the current sensor data. Responsive to determining that the slope value satisfied a threshold criterion associated with a fault detection limit, at least one of an alert is generated or a corrective action performed.

In an aspect of the disclosure, an electronic device manufacturing system configured to obtain a plurality of datasets each comprising sensor output data from a respective sensor of a plurality of sensors each associated with a corresponding process chamber of a plurality of process chambers. The system is further configured to combine the plurality of datasets into an aggregate dataset, generate a distribution of the aggregate dataset, and identify a fault detection limit based on a deviation value generated from the distribution.

In another aspect of the disclosure, an electronic device manufacturing system configured to obtain, by a processor, output data associated with a sensor. The processor further generates a first distribution based on the output data and a set of time values and generates a second distribution based on the output data and a set of tool-life values. The processor further generates a set of coefficients of variations based on the first distribution and the second distribution and generates a set of correlation coefficients based on the first distribution and the second distribution. responsive to the set of coefficients of variations satisfying a first threshold criterion, and the correlation coefficients satisfying a second threshold criterion, the processor assigns the sensor to a group.

A further aspect of the disclosure includes a method according to any aspect or implementation described herein.

A further aspect of the disclosure includes a non-transitory computer-readable storage medium comprising instructions that, when executed by a processing device operatively coupled to a memory, performs operations according to any aspect or implementation described herein.

### BRIEF DESCRIPTION OF THE DRAWINGS

The present disclosure is illustrated by way of example, and not by way of limitation in the figures of the accompanying drawings.

FIG. 1 is a block diagram illustrating an example system architecture, in accordance with some implementations of the present disclosure.

FIG. 2 is a top schematic view of an example manufacturing system, in accordance with some implementations of the present disclosure.

FIG. 3 is a block diagram illustrating an example predictive architecture, in accordance with some implementations of the present disclosure.

FIG. 4A is a set of graphs that illustrates example output values of a sensor categorized as a setpoint sensor, in accordance with some implementations of the present disclosure.

FIG. 4B is a set of graphs that illustrates example output values of a sensor categorized as a tool-life dependent sensor, in accordance with some implementations of the present disclosure.

FIG. 4C is a set of graphs that illustrates example output values of a sensor categorized as a variability sensor in accordance with some implementations of the present disclosure.

FIG. 5A shows an example of a health index graphic user interface (GUI), in accordance with some implementations of the present disclosure.

FIG. 5B shows an example of a heat map GUI, in accordance with some implementations of the present disclosure.

FIG. 5C shows an example of the listing of the respective sensors, in accordance with some implementations of the present disclosure.

FIG. 6A is a graph that illustrates example output values from three process chambers, in accordance with some implementations of the present disclosure.

FIG. 6B is a graph that illustrates the combined (e.g., aggregated) output values, from three process chambers, in the same graph (e.g., as a single dataset), in accordance with some implementations of the present disclosure.

FIGS. 7A-7B are graphs illustrating generating a distribution of the aggregated and normalized data, in accordance with some implementations of the present disclosure.

FIGS. 8A-8H are graphs illustrating different types of control charts that can be generated for various applications, according to aspects of the present disclosure.

FIG. 9 is a flow chart of a method for generating sensor group data, according to aspects of the present disclosure, in accordance with some implementations of the present disclosure.

FIG. 10 is a flow chart of a method of fault detection based on aggregate statistics, according to aspects of the present disclosure.

FIG. 11 is a flow chart of a method for determining a projected control line, according to aspects of the present disclosure.

FIG. 12 is a block diagram illustrating a computer system, according to certain implementations.

### DETAILED DESCRIPTION

Described herein are technologies directed to methods and mechanisms for improving monitoring capabilities using the rate of change of sensor values. The implementations disclosed provide for handling of large amounts of raw and/or statistical data from multiple sensors supplying data about the manufacturing system and processes performed therein. For example, the implementations disclosed can help accurately categorize sensors into groups based on, for example, the behavior of their respective output value. The implementations can further monitor different components and sub-systems across multiple process chambers and accurately detect when an anomaly in a manufacturing process and/or a product of the process arises that indicates a deterioration of the product yield. A sub-system can refer to a pressure sub-system, a flow sub-system, a temperature sub-system and so forth, each sub-system having one or more components. The component can include, for example, a pressure pump, a vacuum, a gas deliver line, etc.

The robotic delivery and retrieval of substrates, as well as maintaining controlled environments in loading, processing, and transfer chambers improve speed, efficiency, and quality of the semiconductor device manufacturing. Typical semiconductor device manufacturing processes often require tens or hundreds of steps, e.g., introducing a gas into a processing chamber, heating the chamber environment, changing a composition of gas, purging a chamber, pumping the gas out, changing pressure, moving a substrate from one position to another, creating or adjusting a plasma environment, performing etching or deposition steps, and so on. The very complexity of the semiconductor manufacturing technology requires processing a constant stream of run-time data from various sensors placed inside the manufacturing system. Such sensor can include temperature sensors, pressure sensors, chemical sensors, gas flow sensors, motion sensors, position sensor, optical sensors, and other types of sensors. The manufacturing system can have multiple sensors of the same (or similar) type distributed throughout various parts of the system. For example, a single processing chamber can have multiple chemical sensors to detect concentration of chemical vapor at various locations within the processing chamber and can similarly have multiple temperature sensors to monitor a temperature distribution. Some or all of the sensors can output a constant stream of data. For example, a temperature sensor can output a temperature reading ever second (or more frequently) so that a single etching step that takes several minutes to perform can be generate hundreds of data points from this sensor alone.

Each sensor (alone or in combination with other sensors) can output data that is indicative of a sudden or gradual detrimental changes in the environment or in the settings of the manufacturing process. In addition, similar sensors in different process chambers can exhibit distinct behavior (e.g., deterioration rate, output variations, etc.), especially after each respective process chamber is subjected to a maintenance routine. In some systems, a detection system can read the data and monitor whether the manufacturing process conforms to the process specifications. However, these systems can feed all available sensor data into the detection system. Such a large number of sensors providing data about multiple substrates being processed in multiple chambers can cause large variability, which can cause difficultly in identifying and classifying anomalies in the data obtained from particular sensors. This can cause the detection system to generate false positives and/or false negatives, resulting in inaccurate diagnostics. Furthermore, the large datasets generated by obtaining data from hundreds or thousands of sensors can require a large processing time. This can cause the detection system to experience increased latency, which can result in missed opportunities to perform adjustments and other corrective actions during the manufacturing process, leading to defective substrates.

Additionally, in some systems, univariate analysis is performed to receive sensor values from a sensor and determine if a sensor value from the sensor exceeds a set limit (e.g., a temperature exceeds a maximum temperature, a fault detection limit). In other systems, multivariate analysis is performed to receive sensor values from multiple sensors, input the sensor values into a set algorithm to receive an output, and determine if the output exceeds a set limit (e.g., a fault detection limit). In some systems, fault detection control charts (e.g., showing univariate or multivariate set fault detection limits) may be generated. Fault detection control charts may be used to detect faults (e.g., in abnormal wafers, in manufacturing equipment, etc.) and to determine a cause of the faults.

Monitoring and maintaining fault detection control charts (e.g., tens of thousands of fault detection control charts) uses a lot of manpower. In some systems, calculating accurate fault detection limits may involve trial and error (e.g., in choosing which sensor values to use for the fault detection limits) and may be time consuming. Due to aging and drift of equipment, fault detection limits generated in some systems may become obsolete. Some systems may derive set limits based on normal products only (e.g., not take into account abnormal products). Some systems may not take into account interaction (e.g., relationships) between sensor statistics. Some systems may not automate against preventative maintenance (PM), set point change, or equipment constant (EC) change.

Aspects and implementations of the present disclosure address these and other shortcomings of the existing technology by automatically grouping sensors and normalizing their output data across multiple process chambers to automatic and adaptive fault detection limits. In addition, aspects and implementation of the present disclosure address the above and other shortcomings of the existing technology by monitoring a rate of change related to the values of a particular sensor, and triggering a corrective action based on the rate of change satisfying a threshold criterion. In particular, a process chamber of a semiconductor device manufacturing equipment can perform each substrate manufacturing process (e.g., a deposition process, a etch process, a polishing process, etc.) according to a process recipe. A process recipe defines a particular set of operations to be performed for the substrate during the process and can include one or more settings associated with each operation. For example, a deposition process recipe can include a temperature setting for the process chamber, a pressure setting for the process chamber, a flow rate setting for a precursor for a material included in the film deposited on the substrate surface, etc. For each step of the process recipe, sensors within the manufacturing equipment can generate raw sensor data related to these and other settings (e.g., measured temperature during each step and/or process run, measured pressure during each step and/or process run, etc.).

Implementation of the present disclosure can sort or categorize, into one or more groups, one or more sensors related to the manufacturing process. Each group can be defined by certain properties or characteristics of the sensors, or the data generated by the sensors. For example, the groups can be defined based on sensor settings, sensor output data types, sensor quality, the sub-system the sensor is correlated to (e.g., flow sub-system, temperature sub-system, pressure sub-system, etc.), etc. The sensor can be grouped from one of more process chambers, or from process chambers of multiple manufacturing systems. In an example, one or more sensors can be categorized into a setpoint group, a tool-life dependent group, or a variability group. The setpoint group can include sensors whose output includes or is expected to include a tight distribution of data over time (e.g., little or no fluctuation of output values over time or over the lifetime of the tool, referred to as tool-life). The tool-life dependent group can include sensors whose output value drifts or changes with time or during the lifetime of the tool. The drift or change can result due to, for example, deterioration of the process chamber and/or components of the process chamber, corrosion, erosion, variation of process chamber coating or conditioning, radio-frequency output time, process chamber emissivity, component life (e.g., life-time of a heater component), etc. The variability group can include sensors that include spikes in output data, sensors that generate inconsistent or asymmetric data, etc. In some implementations, the variability group can include sensors that are not part of the setpoint group nor part of the tool-life dependent group.

Implementation of the present disclosure can also automatically aggregate and normalize sensor data to generate one or more sets of fault detection limits. In an illustrative example where multiple detection limits are used, a first set of control limits can reflect a “caution” limit, which is indicative of data being outside normal range, but not within a range that can cause abnormalities to the substate. A second set of fault detection limits can reflect a critical limit, which is indicative of potential damage occurring during the manufacturing process. To aggregate and normalize the sensor data, the system of the present disclosure can combine data sets of the same sensor from different process chambers into a single dataset. The system can then generate a distribution of the sensor data to identify or generate one or more sets of fault detection limits. For example, the distribution of the sensor data can be a normal or Gaussian distribution. Each standard deviation range of the Gaussian distribution can be related to a set of fault detection limits. In particular, sensor data within the first standard deviation can be identified as normal sensor data. The first standard deviation can be set as the first upper fault detection limit and the lower fault detection limit, and sensor data between the first and second standard deviation can be identified “caution,” sensor data. The second standard deviation can be set as the second upper and lower fault detection limit, and sensor data between the second and third standard deviation (or outside the second standard deviation) can be identified as “critical” sensor data. The limits can be determined for each substrate produced or for specific time periods after maintenance operations are performed on the process chambers. For example, for each substrate, the standard deviation of the corresponding data points can be determined, and the fault detection limits can be identified. This enables the fault detection limits to be moving limits (e.g., updated with each substrate produced) rather than static limits. Thus, the moving limits account for deterioration conditions associated with continued use of the process chambers.

In some implementations, the fault detection limits can indicate that a corrective action or a maintenance operation should be performed. A corrective action can include one or more operations performed to adjust an operating condition (e.g., a parameter of a process recipe) of a process chamber during a process run. For example, a corrective action can include increasing heater current, decrease gas flowrate, etc. A maintenance operation can include a preventative maintenance (PM) operation, a set point change, equipment constant (EC) change, equipment component change, etc.

In some implementations, the system of the present disclosure can generate a fault detection control chart. The detection control chart can be a graph used to monitor sensor data over a duration (e.g., time, substrate cycles, etc.) to determine whether a process variation over the duration is consistent (e.g., with expected limits) or anomalous (e.g., outside the detection limits). The detection control chart can include one or more sets of fault detection limits and a control line. The control line can reflect current sensor data over the duration. In some implementations, a rate of change of two or more sensor values of the control line can be determined. The rate of change can be referred to as a “slope value” and can reflect a rate of change of control chamber wear which impacts a rate of change of process drift. The slope value can be used to project the control line (e.g., via extrapolation) on the fault detection control chart. Responsive to determining that the projected control line will intersect (or cross) a fault detection limit, the system of the present disclosure can generate an alert. Alternatively, the system of the present disclosure can generate an alert in response to determining that the slope value itself satisfies a threshold criterion. Both can be indicative of an approaching issue, thus allowing an operator (e.g., a user) of the system to perform a corrective action or maintenance operation before the fault detection limit is triggered and the approaching issue occurs.

Aspects of the present disclosure result in technological advantages of improving the accuracy of manufacturing fault detection techniques during a manufacturing process. In one example, the aspects of the present disclosure can decrease the occurrence of false positives and false negatives of the fault detection technique. This can result in generating diagnostic data with fewer errors and inaccuracies, which can reduce fabrication of inconsistent and abnormal products, and prevent unscheduled user time or down time. In other aspects of the present disclosure, faults can be predicated. This allows the operator to perform corrective actions or maintenance operations prior to the actual fault occurring, thus preventing possible larger issues. Additionally, aspects of the present disclosure provide significant reduction in time and data required to process the sensor data to detect the possible faults and anomalies.

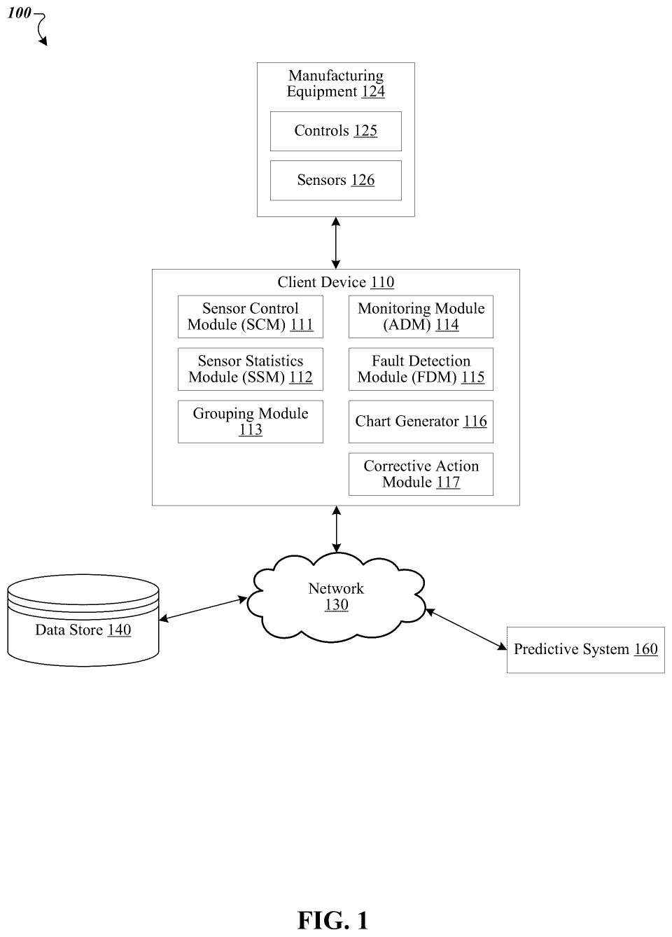

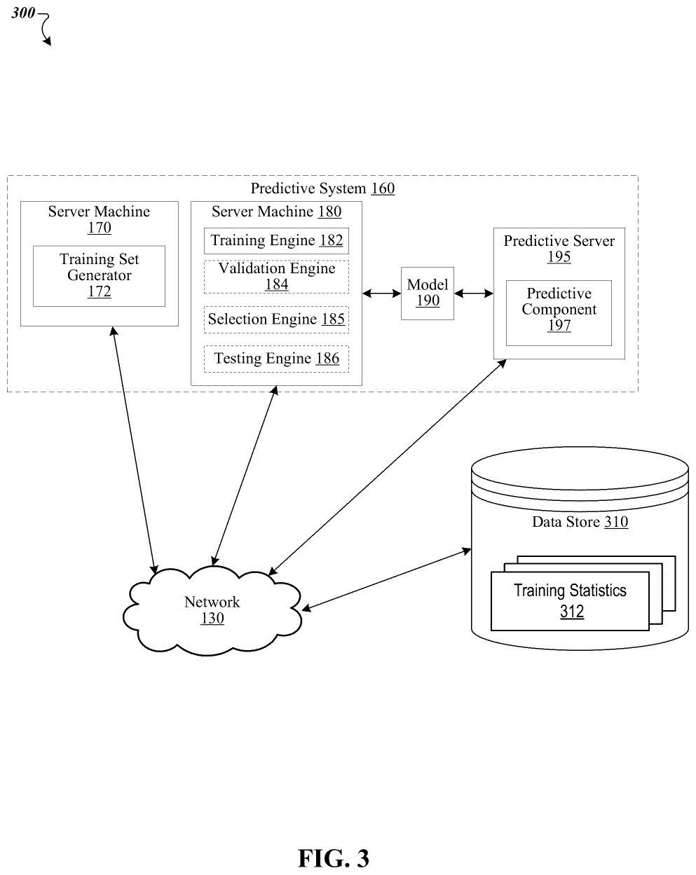

FIG. 1 depicts an illustrative computer system architecture 100, according to aspects of the present disclosure. In some implementations, computer system architecture 100 can be included as part of a manufacturing system for processing substrates. Computer system architecture 100 includes a client device 110, manufacturing equipment 124, predictive system 160 (e.g., to generate predictive data, to provide model adaptation, to use a knowledge base, etc., which will be described in detail in FIG. 3), and data store 140. The manufacturing equipment 124 can include sensors 126 configured to capture data for a substrate being processed at the manufacturing system. In some implementations, the manufacturing equipment 124 and sensors 126 can be part of a sensor system that includes a sensor server (e.g., field service server (FSS) at a manufacturing facility) and sensor identifier reader (e.g., front opening unified pod (FOUP) radio frequency identification (RFID) reader for sensor system). In some implementations, metrology equipment can be part of computer system architecture 100 that includes a metrology server (e.g., a metrology database, metrology folders, etc.) and metrology identifier reader (e.g., FOUP RFID reader for metrology system).

Manufacturing equipment 124 can produce products, such as electronic devices, following a recipe or performing runs over a period of time. Manufacturing equipment 124 can include a process chamber. Manufacturing equipment 124 can perform a process for a substrate (e.g., a wafer, etc.) at the process chamber. Examples of substrate processes include a deposition process to deposit one or more layers of film on a surface of the substrate, an etch process to form a pattern on the surface of the substrate, etc. Manufacturing equipment 124 can perform each process according to a process recipe. A process recipe defines a particular set of operations to be performed for the substrate during the process and can include one or more settings associated with each operation. For example, a deposition process recipe can include a temperature setting for the process chamber, a pressure setting for the process chamber, a flow rate setting for a precursor for a material included in the film deposited on the substrate surface, etc.

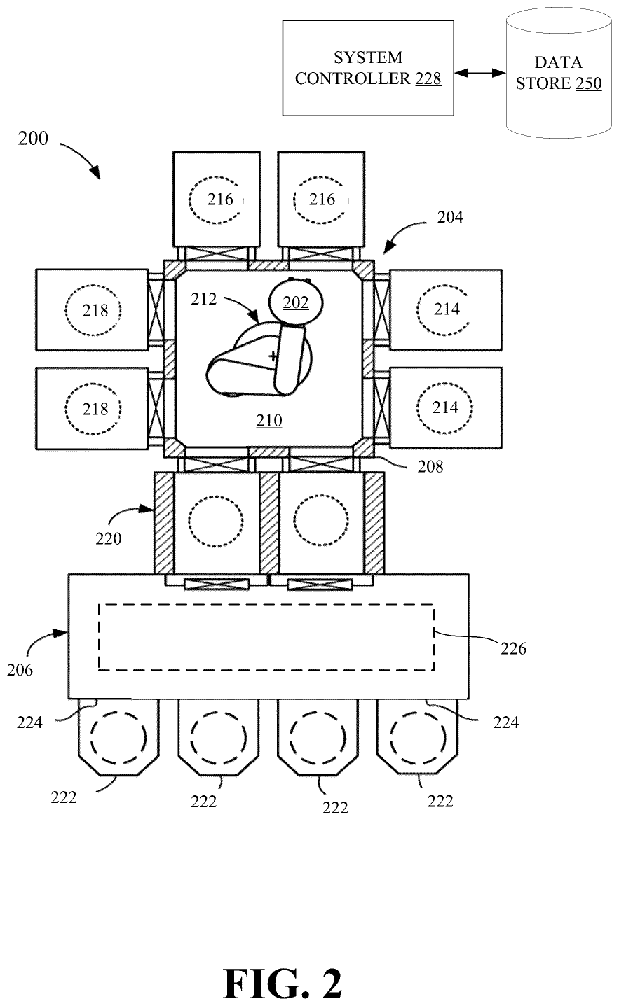

In some implementations, manufacturing equipment 124 includes sensors 126 that are configured to generate data associated with a substrate processed at manufacturing system 100. For example, a process chamber can include one or more sensors configured to generate spectral or non-spectral data associated with the substrate before, during, and/or after a process (e.g., a deposition process, an etch process, etc.) is performed for the substrate. In some implementations, spectral data generated by sensors 126 can indicate a concentration of one or more materials deposited on a surface of a substrate. Sensors 126 configured to generate spectral data associated with a substrate can include reflectometry sensors, ellipsometry sensors, thermal spectra sensors, capacitive sensors, and so forth. Sensors 126 configured to generate non-spectral data associated with a substrate can include temperature sensors, pressure sensors, flow rate sensors, voltage sensors, etc. For example, each sensor 126 can be a temperature sensor, a pressure sensor, a chemical detection sensor, a chemical composition sensor, a gas flow sensor, a motion sensor, a position sensor, an optical sensor, or any and other type of sensors. Some or all of the sensors 126 can include a light source to produce light (or any other electromagnetic radiation), direct it towards a target, such as a component of the machine 100 or a substrate, a film deposited on the substrate, etc., and detect light reflected from the target. The sensors 126 can be located anywhere inside the manufacturing equipment 124 (for example, within any of the chambers including the loading stations, on one or more robots, on a robot blade, between the chambers, and so one), or even outside the manufacturing equipment 124 (where the sensors can test ambient temperature, pressure, gas concentration, and so on). Further details regarding manufacturing equipment 124 are provided with respect to FIG. 2.

In some implementations, sensors 126 provide sensor data (e.g., sensor values, features, trace data) associated with manufacturing equipment 124 (e.g., associated with producing, by manufacturing equipment 124, corresponding products, such as substrates). The manufacturing equipment 124 can produce products following a recipe or by performing runs over a period of time. Sensor data received over a period of time (e.g., corresponding to at least part of a recipe or run) can be referred to as trace data (e.g., historical trace data, current trace data, etc.) received from different sensors 126 over time. Sensor data can include a value of one or more of temperature (e.g., heater temperature), spacing (SP), pressure, high frequency radio frequency (HFRF), voltage of electrostatic chuck (ESC), electrical current, material flow, power, voltage, etc. Sensor data can be associated with or indicative of manufacturing parameters such as hardware parameters, such as settings or components (e.g., size, type, etc.) of the manufacturing equipment 124, or process parameters of the manufacturing equipment 124. The sensor data can be provided while the manufacturing equipment 124 is performing manufacturing processes (e.g., equipment readings when processing products). The sensor data can be different for each substrate.

In some implementations, manufacturing equipment 124 can include controls 125. Controls 125 can include one or more components or sub-systems configured to enable and/or control one or more processes of manufacturing equipment 124. For example, a sub-system can include a pressure sub-system, a flow sub-system, a temperature sub-system and so forth, each sub-system having one or more components. The component can include, for example, a pressure pump, a vacuum, a gas deliver line, a plasma etcher, actuators etc. In some implementations, controls 125 can be managed based on data from sensors 126.

In some implementations, certain sensors 126 and controls 125 can be related to one or more control modules. In particular, each control module can include a set of sensors 126, controls 125, control logic regulating the sensors and/or components, etc. In an illustrative example, the controls modules can include a thermal control module, a plasma control module, a reactant flux control module, and a substrate control module. The thermal control module can include sensors and controls related to providing and maintain a heating environment in a process chamber (e.g., heater, heater sensor, etc.). The plasma control module can include sensors and controls related to creating or adjusting a plasma environment in a process chamber (e.g., plasma etcher, etcher sensor, etc.). The reactant flux control module can include sensors and controls related to the gas flow operations in a process chamber (e.g., gas flow control and sensor, pump, etc.). The substrate control module can include sensors and controls related to substrate properties (e.g., warp experience by a substrate). In certain implementations, sensor data from one or more of the particular control modules can be processed and analyzed, via modules 111-117 and the methods discussed herein, to control the respective operating conditions (e.g., a parameter of a process recipe) associated with said process control module.

The client device 110 can include a computing device such as personal computers (PCs), laptops, mobile phones, smart phones, tablet computers, netbook computers, network connected televisions (“smart TVs”), network-connected media players (e.g., Blu-ray player), a set-top box, over-the-top (OTT) streaming devices, operator boxes, etc. In some implementations, the sensor data (or other data items) can be received from the client device 110. Client device 110 can display a graphical user interface (GUI), where the GUI enables the user to provide, as input, metrology measurement values for substrates processed at the manufacturing system. The client device 110 can include sensor control module (SCM) 111, sensor statistic module (SSM) 112, grouping module 113, monitoring module 114, fault detection module (FDM) 115, chart generator 116, and corrective action module 117.

The SCM 111 can activate sensors, deactivate sensors, place sensors in an idle state, change settings of the sensors, detect sensor hardware or software problems, and so on. In some implementations, the SCM 111 can keep track of the processing operations performed by the manufacturing equipment 124 and determine which sensors 126 to be sampled for a particular processing (or diagnostic, maintenance, etc.) operation of the manufacturing equipment 124. For example, during a chemical deposition step inside one of the processing chambers, the SCM 111 can sample sensors 126 that are located inside the respective processing chamber but not activate (or sample) sensors 126 located inside the transfer chamber and/or the loading station. The raw data obtained by the SCM 111 can include time series data where a specific sensor 126 captures or generates one or more readings of a detected quantity at a series of times. For example, a pressure sensor can generate N pressure readings P(tᵢ) at time instances t₁, t₂, . . . t_{N}. In some implementations, the raw data obtained by the SCM 111 can include spatial maps at a pre-determined set of spatial locations. For example, an optical reflectivity sensor can determine reflectivity of a film deposited on the surface of a wafer, R(xⱼ, yₗ), at a set (e.g., a two-dimensional set) of spatial locations xⱼ, yₖ, on the surface of the film/wafer. In some implementations, both the time series and the spatial maps raw data can be collected. For example, as the film is being deposited on the wafer, the SCM 111 can collect the reflectivity data from various locations on the surface of the film and at a set of consecutive instances of time, R(tᵢ, xⱼ, yₗ).

SSM 112 can process the raw data obtained by the SCM 111 from the sensors 126 and determine statistics representative of the raw data (referred to as “statistics data”). For example, for each or some of the raw sensor data distributions, the SSM 112 can determine one or more parameters of the distribution, such as a mean, a median, a mode, an upper bound, a lower bound, a variance (or a standard deviation), a skewness (third moment), a kurtosis (fourth moment), or any further moments or cumulants of the data distribution. In some implementations, the SSM 112 can model (e.g., via regression analysis fitting) the raw data with various model distributions (normal distribution, log-normal distribution, binomial distribution, Poisson distribution, Gamma distribution, or any other distribution. In such implementations, the one or more parameters can include an identification of the fitting distribution being used together with the fitting parameters determined by the SSM 112. In some implementations, the SSM 112 can use multiple distributions to fit the raw data from one sensor, e.g., a main distribution and a tail distribution for outlier data points. The parameters of the distributions obtained by the SSM 112 can be sensor-specific. For example, for some sensors a small number of parameters can be determined (mean, median, variance) whereas for some sensor many more (e.g., 10 or 20) moments can be determined.

Grouping module 113 can be configured to sort or categorize, into one or more groups, one or more sensors related to the manufacturing process or the manufacturing equipment 124. In some implementations, grouping module can use the sensor data obtained from SCM 111, SSM 112, or any other module or data store that include raw or proceed sensor data. Each group can be defined by certain properties or characteristics of the sensors or the data generated by the sensors. For example, the groups can be defined based on sensor settings, sensor output data types, sensor quality, the sub-system the sensor is correlated to (e.g., flow sub-system, temperature sub-system, pressure sub-system, etc.), etc. The sensor can be grouped from one of more process chambers of manufacturing equipment 124, or from process chambers of multiple manufacturing equipments.

In some implementations, one or more sensors can be categorized into a setpoint group, a tool-life dependent group, or a variability group. The setpoint group can include sensors whose output includes or is expected to include a tight distribution of data over time (e.g., little or no fluctuation of output values over time or over the lifetime of the tool, referred to as tool-life). For example, setpoint sensors can include temperature sensors, radio-frequency power sensors, gas flow sensors, etc. In some implementations, the tight distribution of data can be correlated to the expected results of a process recipe. For example, during the manufacturing process, the process chamber temperature can be expected to be a constant value. Thus, a deviation from the expected value or predefined limits of the expected value can be flagged as a fault by, for example, fault detection module 115.

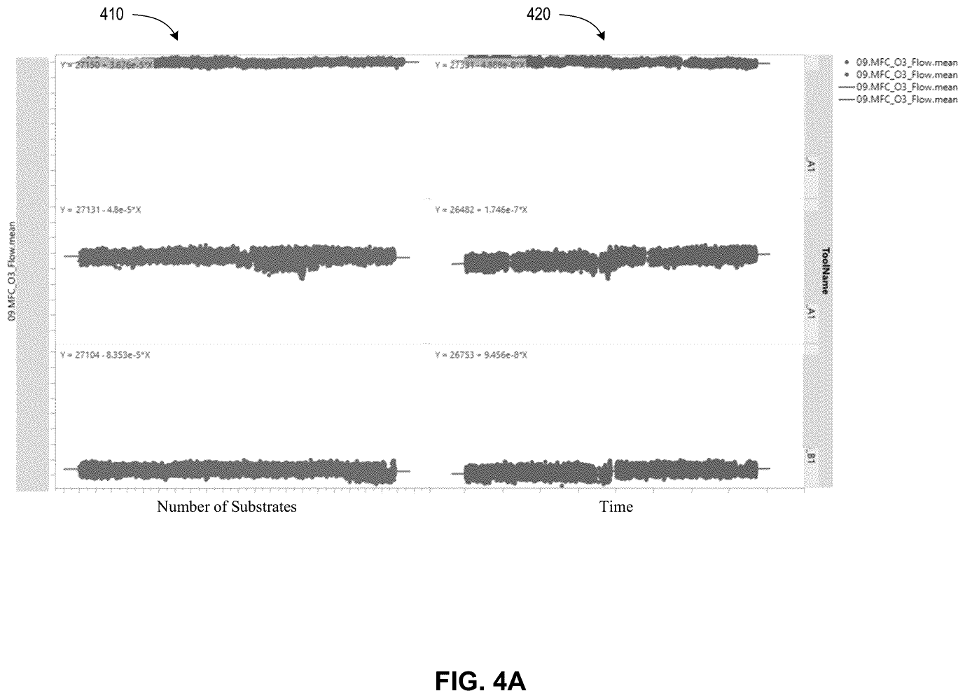

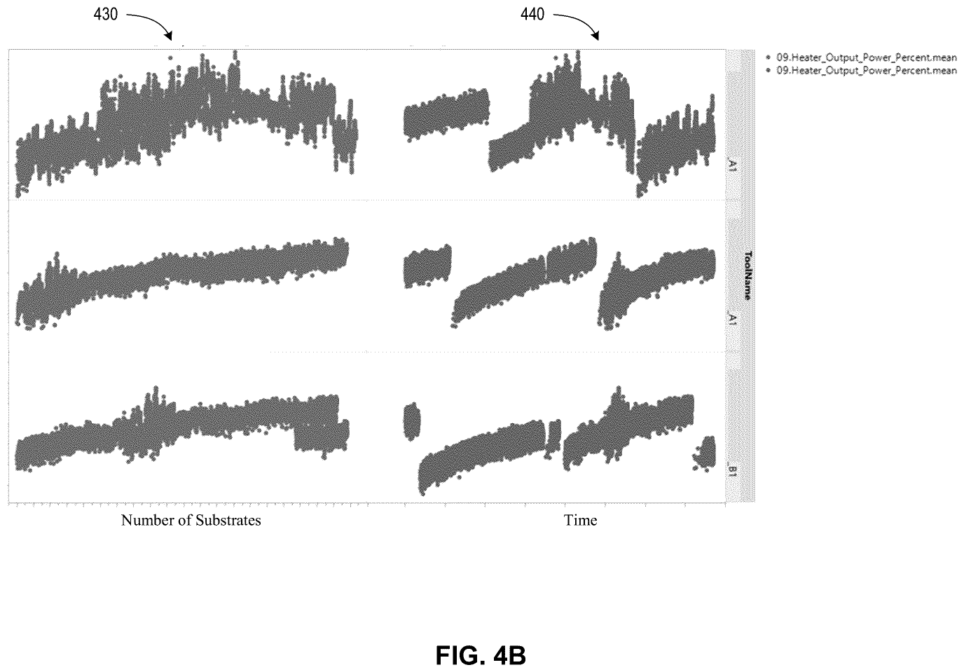

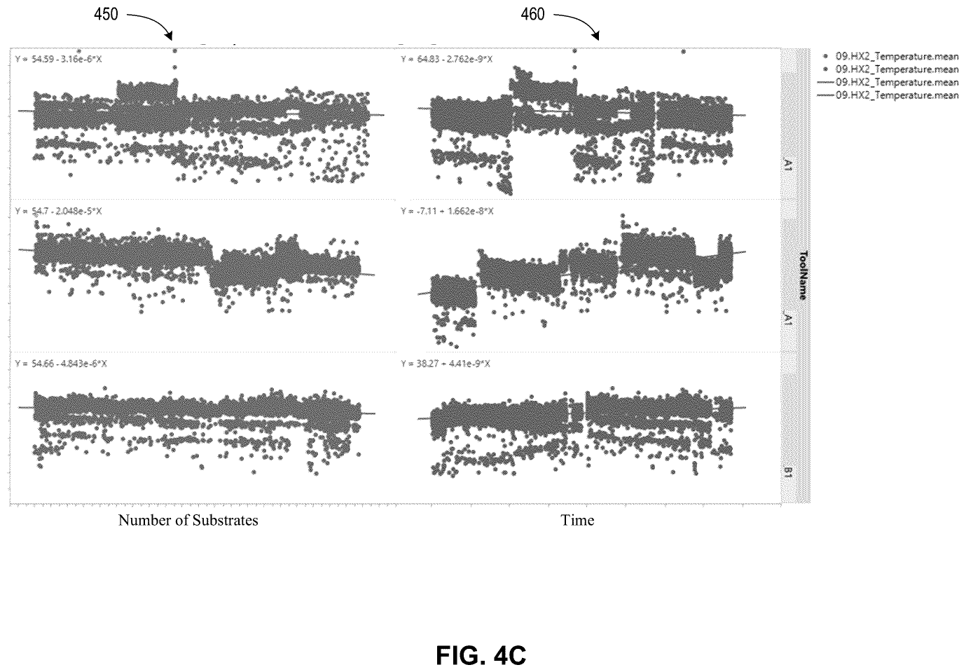

In an illustrative example, FIG. 4A is a set of graphs that illustrates example output values of a sensor categorized as a setpoint sensor, according to aspects of the present disclosure. In particular, column 410 is a set of three graphs showing output values for process chamber flow rates for three different process chambers. The y-axis is indicative of flow rate values and the x-axis is indicative of the number of process runs on substrates. Column 420 is a set of three graphs also showing output values for process chamber flow rates for three different process chambers. The y-axis is indicative of flow rate values and the x-axis is indicative of time. As shown by the sets of graphs illustrated in columns 410 and 420, the flowrate values are consistent over time and the number of substrates.

Returning to FIG. 1, in some implementations, one or more sensors can be categorized into a tool-life dependent group. The tool-life dependent group can include sensors whose output value drifts or changes with time or during the lifetime of the tool. The drift or change can result due to, for example, deterioration of the process chamber and/or components of the process chamber, corrosion, erosion, variation of process chamber coating or conditioning, radio-frequency output time, process chamber emissivity, component life (e.g., life-time of a heater component), etc. In an example, the sensors categorized into the tool-life dependent group can include heater output value, foreline pressure, radio-frequency impedance, etch rate, etc.

In an illustrative example, FIG. 4B is a set of graphs that illustrates example output values of a sensor categorized as a tool-life dependent sensor, according to aspects of the present disclosure. In particular, column 430 is a set of three graphs showing output values for heater output power for three different process chambers. The y-axis is indicative of heater output power percentage values and the x-axis is indicative of the number of process runs on substrates. Column 440 is a set of three graphs also showing output values for heater output power for three different process chambers. The y-axis is indicative of heater output power percentage values and the x-axis is indicative of time. As shown by the sets of graphs illustrated in columns 430 and 440, the heater output power percentage values consistently drift over time and the number of substrates.

Returning to FIG. 1, in some implementations, one or more sensors can be categorized into a variability group. The variability group can include sensors that include spikes in output data, sensors that generate inconsistent or asymmetric data, etc. In some implementations, the variability group can include sensors that are not part of the setpoint group (thus do not have a tight distribution) nor part of the tool-life dependent group (thus do not experience a drift that correlates to time or tool-life). In some examples, sensors that are categorized into the variability group can include reflected power sensors, backside flow sensors, sensors that produce relatively significant noise, whose output value changes over time but is not correlated with the tool-life, those that have no effect on a tool, etc.

In an illustrative example, FIG. 4C is a set of graphs that illustrates example output values of a sensor categorized as a variability sensor, according to aspects of the present disclosure. In particular, column 450 is a set of three graphs showing output values for process chamber temperature for three different process chambers. The y-axis is indicative of mean temperature values and the x-axis is indicative of the number of process runs on substrates. Column 460 is a set of three graphs also showing output values for process chamber temperature for three different process chambers. The y-axis is indicative of mean temperature values and the x-axis is indicative of time. As shown by the sets of graphs illustrated in columns 450 and 460, the mean temperature values include many value that deviate from the mean and can be attributed to noise.

Returning to FIG. 1, although implementations of the present disclosure will be discussed in relation to sensor groups, in some implementations, grouping module 113 can be configured to organize, into one or more groups, one or more data items. A data item can include sensor data, task data, contextual data, statistics data, etc. In some implementations, the data items can first be combined into a set(s) of “arrays.” An array can include a combination of data items according to a predefined format or pattern. In some implementations, each array can include a particular sensor (e.g., chamber pressure sensor, heater current sensor, etc.), a statistic data type (e.g., mean, range, etc.), and a recipe portion identifier (e.g., step one, step five, entire recipe, etc.). For example, an array can be indicative of the average heater voltage during step three of a particular process recipe.

In some implementations, grouping module 113 can use one or more algorithms to categorize sensors into one or more specific groups. In some implementations, grouping module 113 can use a detection algorithm to categorize sensors into one or more specific groups. The detection algorithm(s) can be configured to correlate each sensor to one or more predefined groups based on one or more predefined criterion. In an implementation, the detections algorithm can first implement a distribution algorithm (e.g., a Gaussian distribution algorithm, or any other algorithm or formula capable of determining deviations in datasets) to generate distributions, for each sensor, based on time and tool-life.

The detections algorithm can then calculate coefficients of variations and correlations for both distributions (e.g., the distribution based on time and the distribution based on tool-life. The coefficient of variation (CV) is the ratio of the standard deviation to the mean and shows the extent of variability in relation to the mean of the population. In one example, the coefficient of variation can be determined by dividing a population standard deviation by the population mean. A correlation coefficient is a number between −1 and 1 that indicates the strength and direction of a relationship between variables (e.g., a statistical relationship between two variables). In particular, the correlation algorithm can be configured to identify pairings between corresponding output value of both distributions.

In some implementations, the correlation algorithm can include a clustering algorithm that can receive, as input data, the corresponding sensor value from both distributions, and generate, as output data, the indications of correlations. In some embodiments, the grouping module 113 can generate the output data using, for example, a clustering algorithm, Clustering algorithms can include a K-means clustering algorithm, a density-based spatial clustering of applications with noise (SBSCAN) algorithm, a Spectral Clustering algorithm, a Ward clustering algorithm, a Birch clustering algorithm, or any other clustering algorithm.

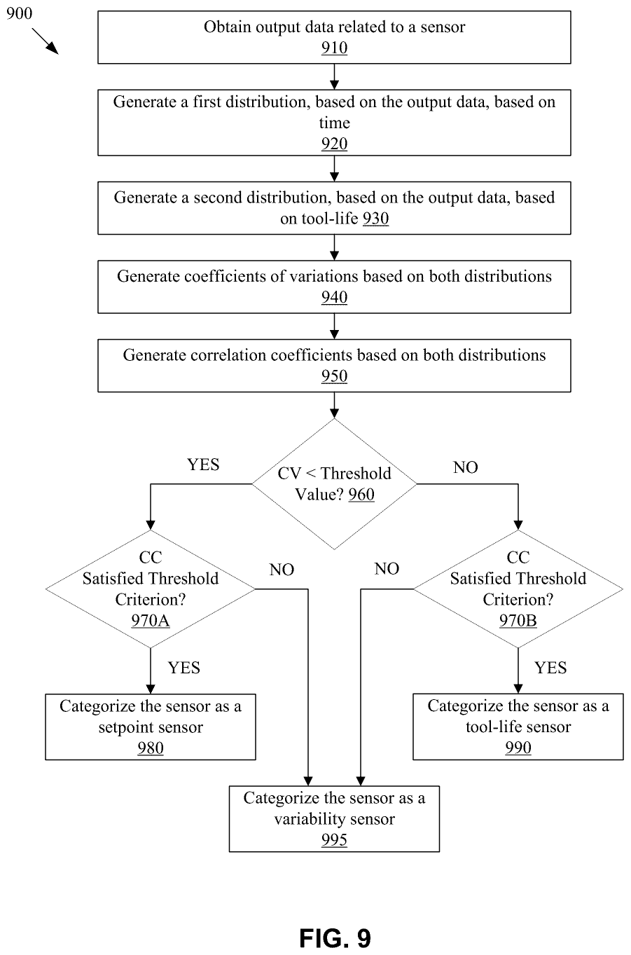

Responsive to coefficients of variations satisfying a setpoint criterion (e.g., the coefficients of variations are below a threshold value and the correlations are within a certain range to the value 1), the grouping module 113 can categorize those sensors as setpoint sensors. Responsive to coefficients of variations satisfying a tool-life dependent criterion (e.g., the coefficients of variations are above a threshold value and the correlation of the tool life data across multiple process chambers is within a certain range to the value 1), the grouping module 113 can categorize those sensors as tool-life dependent sensors. Responsive to neither the setpoint criterion nor the tool-life dependent criterions being satisfied, the grouping module 113 can then categorize those sensors as variability sensor. Further details regarding the distributions algorithm are discussed in FIG. 9.

In some implementations, grouping module 113 can use one or more machine learning models (e.g., model 190) to categorize sensors into one or more specific groups. In particular, grouping module 113 can input sensor data (e.g., sensor values, sensor characteristic data, etc.) into the machine learning model, and receive, as output, data indicative of group assignments (e.g., to which group each sensor should be assigned). The machine learning model can be generated by the predictive system 160, which is discussed with regards to FIG. 3.

In some implementations, grouping module 113 can use an auto sensor ranking algorithm. The auto sensor ranking algorithm can group sensors based on each sensor's importance or significance. The importance or significance of each sensor can be determined by comparing the value from similar or the same sensor during different process runs, from different process chambers, from good process runs (e.g., where the substrate is fabricated exactly or close to desired specifications, versus where the substrate is fabricated with defects or deformations), etc. In an illustrative example, grouping module 113 can monitor a set of process runs of a process recipe to collect runtime data from a set of sensors of manufacturing equipment 124. Grouping module 113 can determine qualitative data describing each of the substrates produced by the set of process runs of the process recipe. Grouping module 113 can characterize each of the process runs into a respective, predetermined group based on an analysis of the qualitative data. Grouping module 113 can then generate a data model, based on the collected runtime data, which describes, for each of the plurality of groups, at least one of the patterns of sensor data for the respective group and/or a relative importance of each of a set of sensor types of the set of sensors in indicating the respective group. In some implementations, grouping module 113 can perform a multivariate analysis of additional runtime data collected during at least one subsequent run of the recipe within the manufacturing environment to classify the at least one subsequent run into one of the of the groups, by determining which pattern of sensor data specified within the data model best fits the additional runtime data. Upon classifying the at least one subsequent run of the recipe into the particular group, grouping module 113 can generate an output (e.g., for display on an interface of client device 110) depicting a ranking of at least two of the sensor types based on the additional runtime data and the description of relative importance of each of the plurality of sensor types for the particular group within the data mode. Further details regarding the auto sensor ranking algorithm are discussed in U.S. Pat. No. 11,054,815, which is, hereby, incorporated by reference in its entirety.

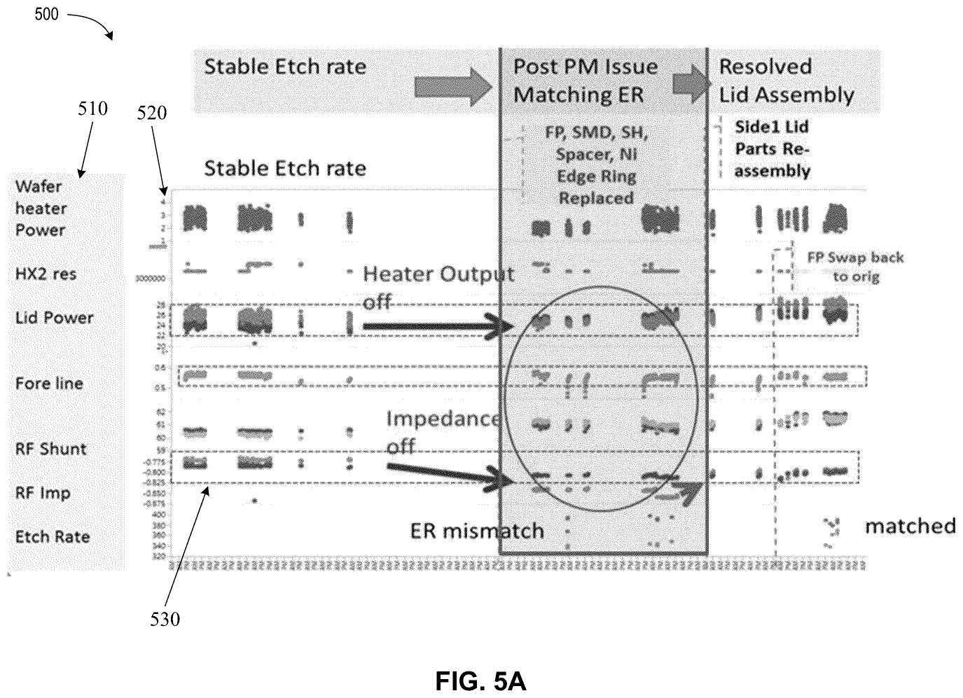

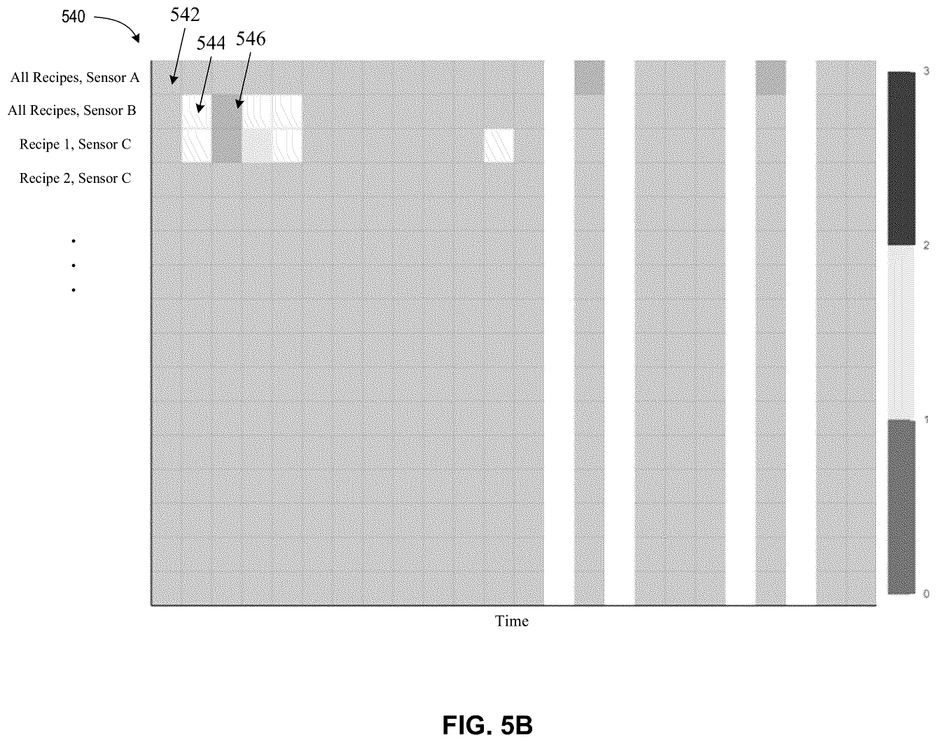

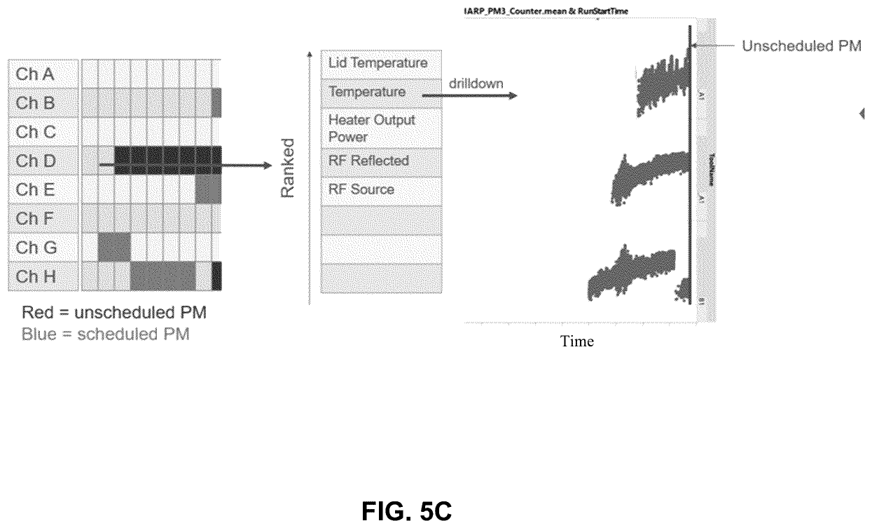

Monitoring module 114 can generate one or more graphical user interfaces (GUI) to monitor the one or more sensor groups. In some implementations, monitoring module 114 can generate a health index GUI configured to track the output data generated by the sensors of one or more sensor groups. The health index GUI can display each sensor of one or more sensor groups (or a subset of sensors from one or more sensor groups) and their respective output values over a timeline (e.g., a time, a number of process runs, etc.). In some implementations, for one or more of the displayed sensors, one or more limits can be displayed. The limits can be indicative of a deviation, a fault, an anomaly, or any other indication of abnormal or irregular data. In some implementation, the limit may be related to a fault detection limit, which is discussed below. In an illustrative example, FIG. 5A shows an example of a health index GUI 500, according to aspects of the present disclosure. Each listed sensor 510 (e.g., a set of sensors assigned to the tool-life dependent group) includes a corresponding set of output parameters or values 520 displayed on the y-axis. The x-axis displays post-maintenance process runs. For some sensors, visual limits can be displayed (e.g., for lid power, foreline pressure, and radio-frequency shunt impedance). For example, limits 530 display the acceptable impedance values for the process chamber(s). The limit values can be set, for example, via user input. In instances where the sensor values exceed the limit values, monitoring module 114 can generate an alert (e.g., display or send a prompt, generate a sound, etc.). In some implementations, in response to a sensor value exceeding a limit value, a corrective action, via corrective action module 116, can be performed.

In some implementations, monitoring module 114 can generate a heat map configured to track the output data generated by the sensors of one or more sensor groups. FIG. 5B shows an example of a heat map GUI 540, according to aspects of the present disclosure. In some implementations, the y-axis displays predetermined sets of sensor output data over a time (e.g., a set of days represented by the x-axis). The sensors listed on the y-axis can belong to a particular group (e.g., the setpoint group, the tool-life group, etc.). In some implementations, each listing on the y-axis can show fault indicative data, for a particular sensor, from a set of process chambers. For example, the first row shown in GUI 540 can show fault indicative data for sensor A in each process chamber that use any type of process recipe. The fault indicative data, in one example, can indicate whether the data output from each of the particular sensors is within normal range (shown by shade 542), at or near a fault limit (shown by shade 544), or exceed the fault limit (shown by shade 546). In some implementations, if a predetermined amount of the particular sensors satisfies a threshold criterion (e.g., are at or exceed a fault limit), the fault indicative data can visually represent this by changing color or shade. For example, fault indicator 544 indicates that at least one sensor B exceeded the fault limit. In some implementations, a fault indicator (e.g., fault indicator 542) can be selected (e.g., via user input) to show a listing of all of the respective sensors (e.g., each sensor A in each process chamber). FIG. 5C shows an example of the listing of the respective sensors. As shown, process chamber D experienced a fault.

Fault detection module 115 can process, aggregate, and analyze the sensor data collected by SCM module 111, the statistics collected by the SSM 112, and/or the grouping module 113. In particular, fault detection module 115 can automatically aggregate and normalize sensor data to generate fault detection limits. A fault detection limit can be an indicator that a sensor's output data is indicative of a fault or anomaly. In some implementation, multiple fault detection limits can be used. For example, a first fault detection limit can reflect a “caution” limit (or fault), which is indicative of data being outside normal range, but not within a range that can cause abnormalities to the substate. A second fault detection limit can reflect a critical limit (or fault), which is indicative of potential damage occurring during the manufacturing process.

In some implementations, data from a particular type of sensor (from one or more process chambers) can be aggregated and normalized. For example, for each process chamber, heater output data can be obtained, aggregated, and normalized. In some implementations, fault detection module 115 can aggregate and normalize data for each type of sensor categorized into a group.

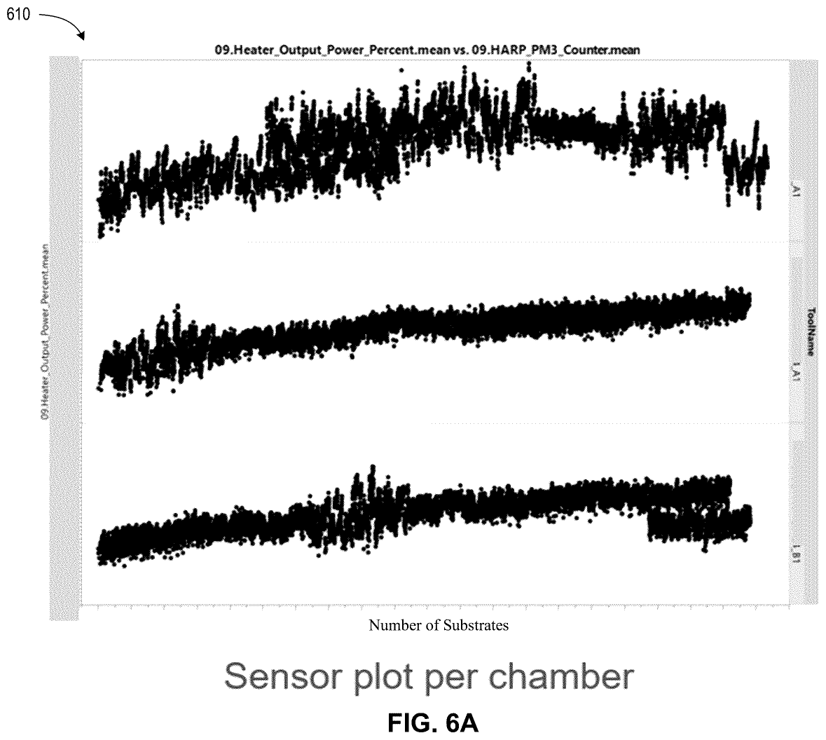

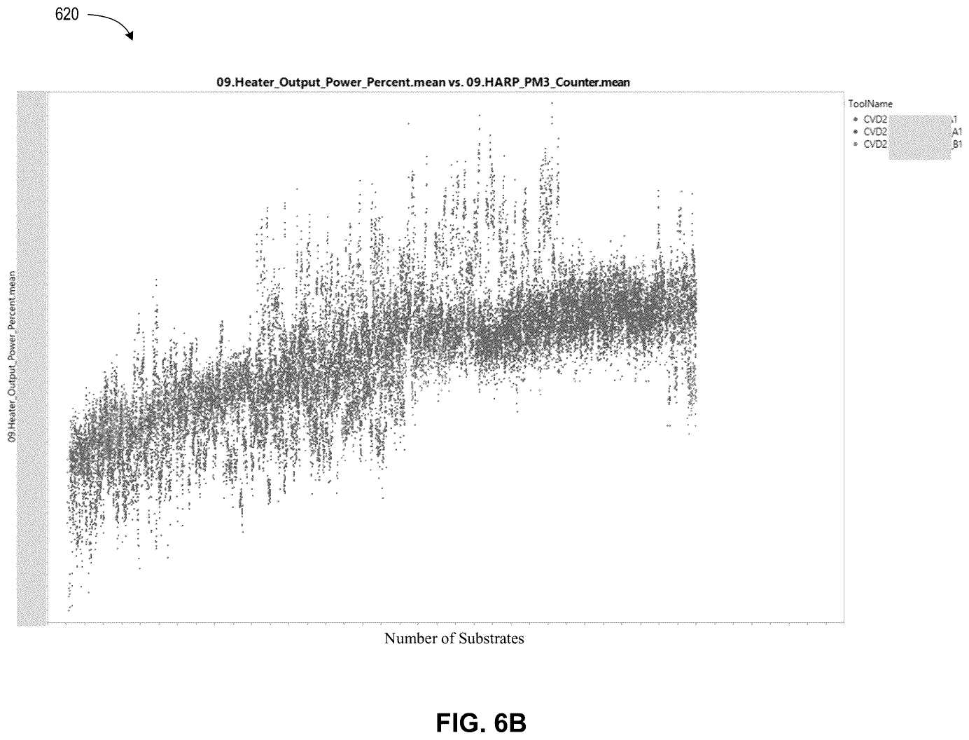

In some implementations, to aggregate and normalize the sensor data, fault detection module 115 can combine different data sets into a single dataset. In an illustrative example, FIG. 6A is a graph 610 that illustrates example output values from three process chambers, according to aspects of the present disclosure. In particular, FIG. 6A illustrates, for three different process chambers, the respective heater output power percent mean over a number of substrates produced. FIG. 6B is a graph 620 that illustrates the combined (e.g., aggregated) output values, from three process chambers, in the same graph (e.g., as a single dataset), according to aspects of the present disclosure.

Fault detection module 115 can further generate a distribution of the sensor data to identify or generate one or more fault detection limits. For example, the distribution of the sensor data can be a normal or gaussian distribution. Fault detection module 115 can then identify a normal data range and set one or more fault detection limits. In one example, the fault detection limits can be based on standard deviations of the data distribution. For example, fault detection module 115 determine the mean value of the aggregated dataset and identify the sensor output values within the first standard deviation of the mean value, identify the sensor values between the first standard deviation and the second standard deviation, and so forth. Each standard deviation range can be related to a fault detection limit. For example, sensor data within the first standard deviation can be identified as normal sensor data. The first standard deviation can be set as the first fault detection limit, and sensor data between the first and second standard deviation can be identified “caution,” sensor data. The second standard deviation can be set as the second fault detection limit, and sensor data between the second and third standard deviation (or outside the second standard deviation) can be identified as “critical” sensor data. In some implementations, the fault detection limits can be set using a training set of data. In some implementations, the fault detection limits can be set and/or adjusted using real-time data.

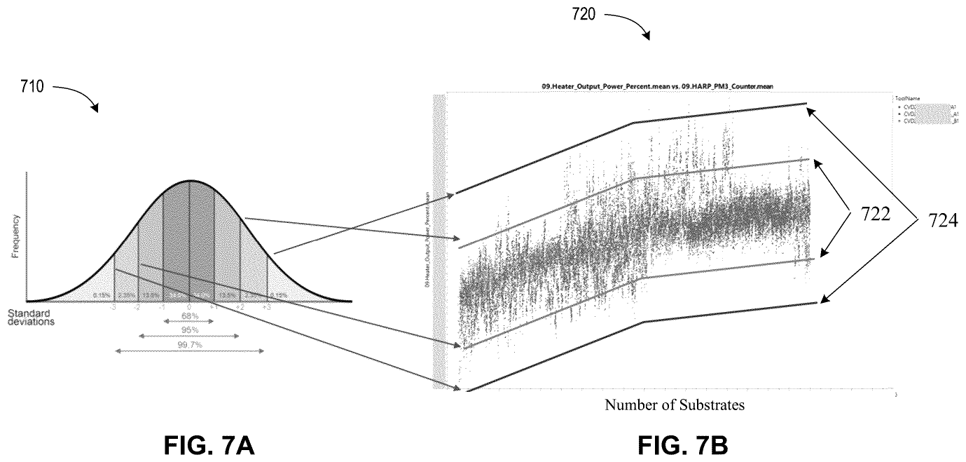

FIGS. 7A-7B are graphs 710, 720, respectively, illustrating generating a distribution of the aggregated and normalized data, according to aspects of the present disclosure. In particular, FIG. 7A shows a standard distribution of the data (e.g., the heater output data discussed in FIGS. 6A-6B) represented by a bell curve. FIG. 7B illustrates a detection control chart with fault detection limits (determined from the standard deviations of the sensor data) over the sensor data. In particular, the first standard deviation can correspond to the first set of fault detection limits 722 (e.g., caution fault detection limits), and the second standard deviation can correspond to the second set of fault detection limits 724 (e.g., critical fault detection limits). The limits can be determined for each substrate produced (e.g., the values along the x-axis). For example, for each substrate, the standard deviation of the corresponding data points can be determined, and the fault detection limits can be identified. This enables the fault detection limits to be moving limits (e.g., updated with each substrate produced) rather than static limits. In some implementations, the time after zero on the x-axis represented the post-maintenance period of the process chambers. Thus, the moving limits account for deterioration conditions associated with continued use of the process chambers.

Returning to FIG. 1, in some implementations, the fault detection limits can be determined using training data comprising ideal or near ideal process runs (e.g., process runs that contain no abnormalities). In some implementations, the groups can be updated based on the data triggering the fault detection limits. For example, during production runs, fault detection module can determine that certain censors deviate past certain fault detection limits (e.g., critical limits). Accordingly, those sensors be categorized as setpoint sensors, and added to the setpoint group.

It is noted that the example for aggregating and normalizing the sensor data are used by way of illustrative example, and that other method can be used. In some implementations, fault detection module 115 can pre-process, reduce the dimensionality of the sensor statistics, process the reduced representations of statistics, normalize, and/or process using a neural network to determine fault detection limits, etc. At least some of the listed operations can include machine learning.

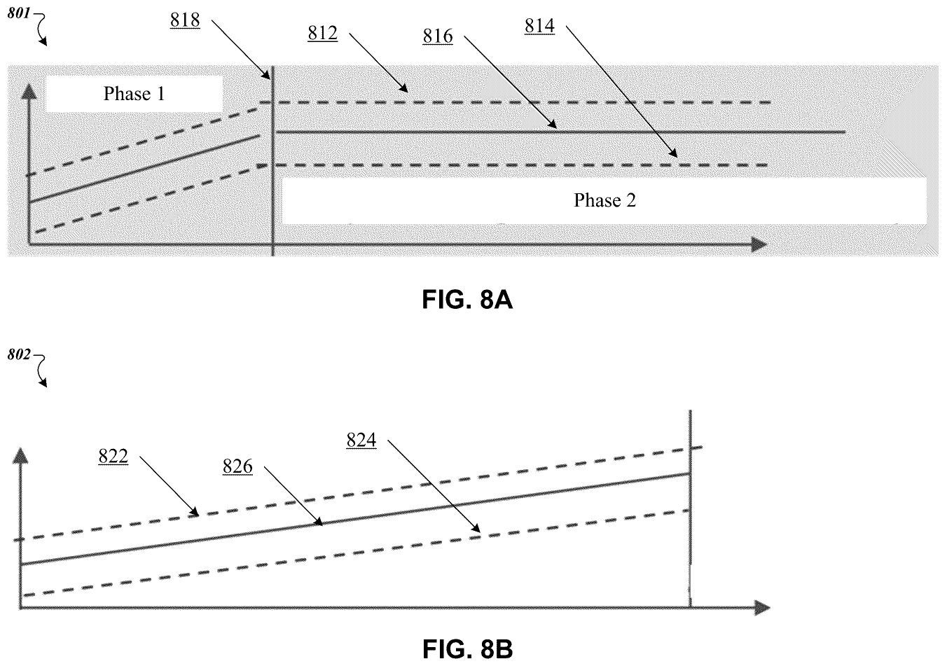

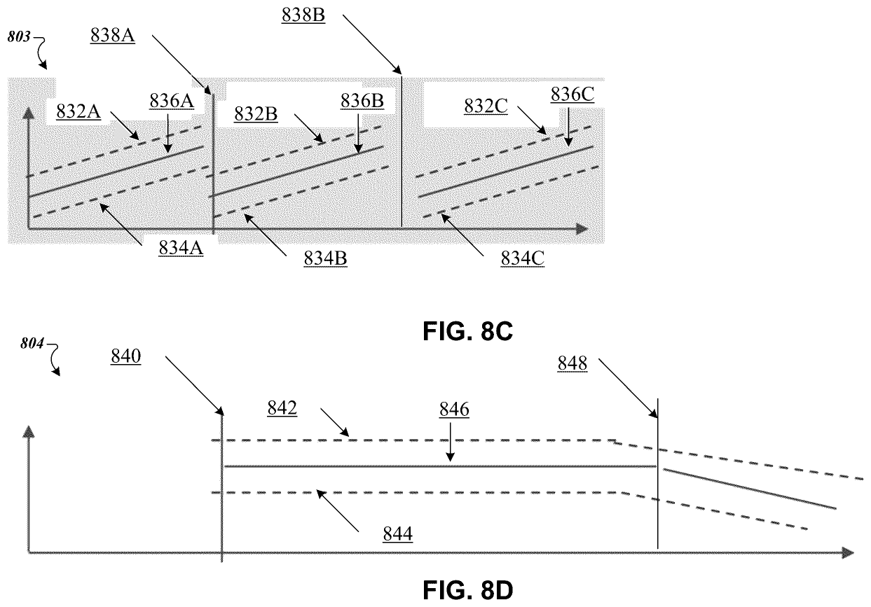

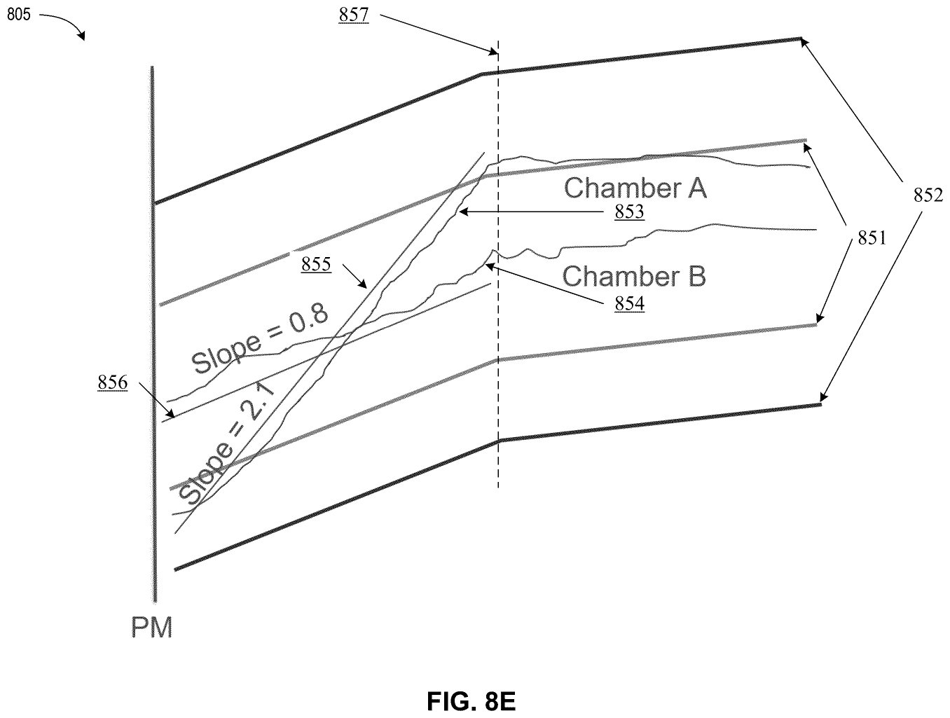

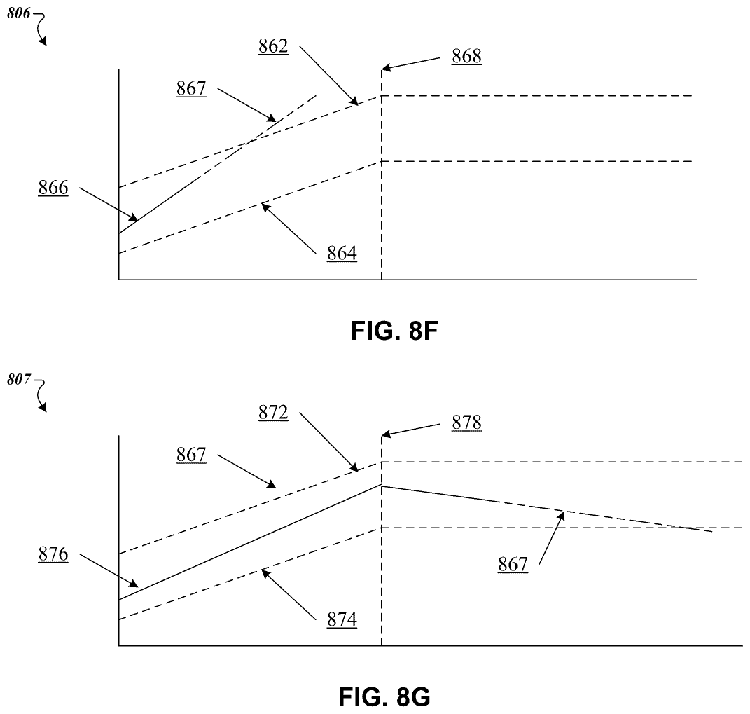

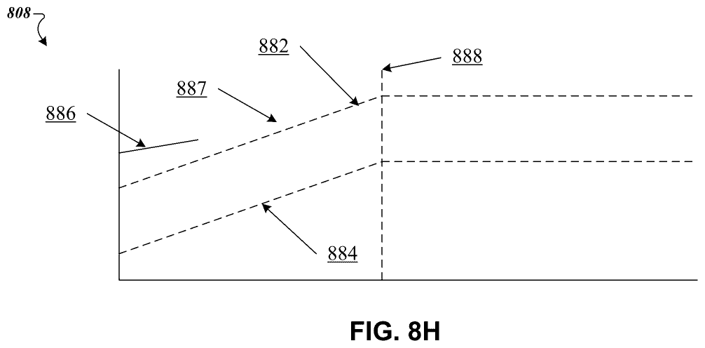

Chart generator 116 can generate a fault detection control chart. The fault detection control chart can be any type of chart, graph, plot, or other visual representation used to display (on a GUI of, for example, client device 110) the monitoring of sensor data over a duration (e.g., time, substrate cycles, etc.) to determine whether a process variation over the duration is consistent (e.g., within expected limits) or anomalous (e.g., outside the detection limits). The fault detection control chart can include one or more sets of fault detection limits and a control line. Each set of fault detection limits can include an upper fault detection limit and a lower fault detection limit. The control line can reflect current sensor data over the duration. As such, chart generator 116 can first generate the fault detection control chart by providing (e.g., depicting or plotting) the fault detection limits (that were generated using fault detection module 115) on a graph. In response to receiving corresponding current sensor data, charge generator can plot the sensor data on the detection control chart. The two or more sensor data points can be referred to as the control line. As will be explained in detail in FIGS. 8A-8H, different types of control charts can be generated for various applications. These examples are intended to be illustrative, and not restrictive.

FIG. 8A is an illustration of a detection control chart 800 used in relation to chamber seasoning operations, according to aspects of the present disclosure. A preventative maintenance can routinely be performed on a process chamber. The preventative maintenance can include cleaning the process chamber, repairing process chamber components, performing adjustment or tunings to the components, replacing one or more components, and/or any other procedures that can be performed on the components of the process chamber to reduce the chances of equipment failure. After a preventative maintenance is performed, the process chamber (starting with t=0) can experience a conditioning phase. During the conditioning phase, process runs can be performed on a set of substrates until the process chamber is in a steady state phase (a phase where the settings associated with a process recipe (e.g., temperature setting(s), pressure setting(s), flow rate setting(s), etc.) are expected to be constant or change at a constant rate. The conditioning phase can be, for example, a seasoning phase where a layer of material (e.g., silicon oxide layer) is built over the chamber walls before a substrate is introduced into the chamber for processing. The deposited seasoning layer can occur due to the gas(ses) used in a process recipe and can reduce the likelihood that contaminates will interfere with subsequent processing steps. During the seasoning layer buildup, each subsequent substate can result in different settings being required for obtaining the desired results. For example, the heater power may need to be slightly increased with each subsequent substrate due to the growing seasoning layer absorbing more heat. In an example, the seasoning phase can include 50 substrates, 100 substrates, or any other number of substrates until subsequent settings values are no longer affected by process runs on subsequent substrates, at which point the process chamber is in a steady state.

As shown in FIG. 8A, fault detection control chart 800 includes a set of fault detection limits (upper fault detection limit 812 and lower fault detection limit 814), control line 816, and transition line 818. The x-axis can represent a duration (e.g., time, substrate cycles, etc.) and the y-axis can represent sensor values (e.g., heater power, RF power, heater current, pressure, flow rate, emissivity, etc.). The duration can be indicative of a production run. A production run can reflect a number of substrates processed on the process chamber since the last maintenance operation was performed. The set of control limits can relate to the settings parameter that is to be monitored. The transition line 818 can be indicative of different phases from which the sensor data related to a particular settings parameter is collected. As shown, the left side (phase 1) of transition line 818 can include sensor data collected while the process chamber is being seasoned, and the right side (phase 2) of transition line 818 can include sensor data collected when the process chamber is in a steady state. Since the steady state phase of detection control chart 800 is expected to include a tight distribution of data over time (e.g., little or no fluctuation of output values over time or tool lifetime), detection control chart 800 can be used for sensors in the setpoint group.

The control line reflects the sensor data collected. In some implementations, the control line can be generated by determining a line of best fit of the sensor data (or using any other method capable of determining a relationship between the sensor data). A line of best fit is a straight line that minimizes the distance between it and some data. The line or best fit can be determined using the least squares method, or any other formula, equation, or method. The control line can be updated at predetermined intervals (e.g., in response to each current senor value plotted, in response to each second current sensor line value plotted, etc.). As shown in FIG. 8A, the control line stays within the control limits throughout the seasoning phase and the steady state phase. As such, no fault is tripped.

Chart generator 116 can obtain and plot current sensor data on a detection control chart. In some implementations, chart generator 116 (or fault detection module 115) can determine a y-intercept related to the control line and/or a slope of the control line. The y-intercept can be an initial value obtained at t=0, or determined by determining the slope value of two of more sensor values of the control line. In some implementations, the slope value can be determined using the slope equation y=m*x+b, where m is the slope value, b is the y-intercept, x refers x-axis values, and y refers to y-axis values. In some implementations, responsive to the y-intercept value satisfying a threshold criterion (e.g., being outside of the set of control limits), chart generator can indicate that a fault occurred. For example, chart generator 116 can plot the first sensor value received at x=0 and the appropriate y-coordinate. Chart generator 116 can then determine that the first sensor value (e.g., the y-intercept value) is above the upper fault detection limit or below the lower fault detection limit. In response, chart generator 116 can determine that a fault occurred and issue an alert and/or perform a corrective action.

In some implementations, chart generator 116 can project the control line (e.g., using the slope value, extrapolation, or any other formula or method) to determine whether the projected control line satisfies a threshold criterion (e.g., being outside of the set of fault detection limits). In response to determining that the projected control line satisfies the threshold criterion, chart generator 116 can indicate that a fault occurred and issue an alert and/or perform a corrective action.

To generate the projected control line, chart generator 116 can first determine a slope value of the control line. Chart generator 116 can then graph projected sensor data point based on the slope value. The projected sensor data points can be graphed for a predetermined duration (e.g., for 50 subsequent substates, for a length or sub-length of the fault detection limit(s), etc.). The projected control line can be re-graphed in predetermined intervals (e.g., for every five current data point plotted, for every current data point plotted, etc.).

In some implementations, the projected control line can be used as a visual aid to an operator. In some implementations, chart generator 116 can determine whether a fault detection limit will be crossed by determining whether the control line will intersect with either of the fault detection limits. For example, the control line can be represented as y=m₁*x+b₁, where m₁ is the slope of the control line and b₁ is the y intercept of the control line. The fault detection line can be represented as y=m₂*x+b₂, where m₂ is the slope of the fault detection line and b₂ is the y intercept of the fault detection line. Chart generator 116 can then set the respective y values equal to each other and determine the x value, which reflect the intersection value. Chart generator 116 can then determine whether determined x value is satisfies a threshold criterion. The threshold criterion can be a reflecting, for example, the end of a phase (e.g., the end of the seasoning phase). Responsive to determining that the x value is prior to the end of the phase, an alert can be generated.

In some implementations, chart generator 116 can determine an upper slope limit and a lower slope limit based on the slope of the respective fault detection limits, the phase indicator, and the slope of the control line. For example, chart generator 116 can set the x value to the intersection of one of the fault detection limits (e.g., upper fault detection limit) and the phase indicator. Chart generator 116 can then determine a trigger slope value of the control line (based on its y-intercept value) that would intersect said value. Chart generator 116 can then trigger an alert in response to determining that slope value of subsequently determined control lines for the process chamber are above the trigger control value. A trigger slope value can also be determined for the lower fault detection limit and chart generator 116 can trigger an alert in response to determining that slope value of subsequently determined control lines for the process chamber are below this trigger control value.

FIG. 8B is an illustration of a fault detection control chart 802 used in relation to sensors whose output value drifts or changes with time or during the lifetime of the tool, according to aspects of the present disclosure. In some implementations, detection control chart 802 can be used in relation to sensor in the tool-life dependent group, which can occur due to erosion, continuous change in a parameter (e.g., the pressure in a liquid delivery system increasing/decreasing due to the depletion of the liquid), ampoule life, etc. Fault detection control chart 802 includes a set of fault detection limits (upper fault detection limit 822 and lower fault detection limit 824) and control line 826. The x-axis can represent a duration and the y-axis can represent a settings parameter.

FIG. 8C is an illustration of a fault detection control chart 804 used in relation to scheduled cleanings of a process chamber, according to aspects of the present disclosure. A cleaning of a process chamber or parts of the process chamber can be need due to contaminate buildup, seasoning deterioration, etc. Fault detection control chart 804 includes a set of fault detection limits (upper fault detection limit 832A-832C and lower fault detection limit 834A-834C), scheduled cleaning indicators 838A-838B, and control line 836A-836C. The x-axis can represent a duration and the y-axis can represent sensor values. As shown, a certain number of substrates can be processed until processing is suspended for process chamber cleaning. After the cleaning, the fault detection limits are reset. Responsive to a projected control line triggering a fault detection limit or a y-intercept value triggering a fault detection limit, an alert can be issued or a corrective action can be performed. For example, an alert can indicate to the operator that a cleaning should be performed earlier than planned, thus preventing inferior substrates from being manufactured.

FIG. 8D is an illustration of a detection control chart 806 used in relation to component damage, according to aspects of the present disclosure. A process chamber can experience damage to one or more components that requires the component to be replaced. The damage can be due to normal wear and tear. Fault detection control chart 806 includes a set of fault detection limits (upper fault detection limit 842 and lower fault detection limit 844), steady state indicator 840, control line 846, and end-of-life indicator 848. The x-axis can represent a duration and the y-axis can represent sensor values. As shown, the steady state phase begins at steady state indicator 840. A certain number of substrates can be processed until end-of-life indictor 848 is reached, upon which the slope of the fault detection limits is changed to account for one or more deteriorating components. The slope of the control line 846 can be periodically measured and a projected control line can be determined. Responsive to a projected control line triggering a fault detection limit prior to the end-of-life indictor 848 or after the end-of-life indictor 848, an alert can be issued or a corrective action can be performed. For example, an alert can indicate to the operator that a component is deteriorating faster than expected and should be change sooner than scheduled.

FIG. 8E is a graph 808 showing a detection control chart with multiple sets of control limits, according to aspects of the present disclosure. As shown, the detection control chart 805 includes two sets of fault detection limits, caution faults 851, and critical faults 852, and phase shift indicator 857. Sensor data obtained for process chamber A 853 can be used to determine control line 855, which has a slope value of 0.8. Sensor data obtained for process chamber B 854 can be used to determine control line 856, which has a slope value of 2.1. As shown, the sensor data generated by process chamber A indicates a fault with the process chamber as the slope crosses multiple faults detection limits.

FIG. 8F is an illustration of a fault detection control chart 806 generating a project control line, according to aspects of the present disclosure. Fault detection control chart 806 includes a set of fault detection limits (upper fault detection limit 862 and lower fault detection limit 864), phase shift indicator 868, control line 866, and projected control line 867. In this implementation, the left side of phase shift indicator 868 can refer to the seasoning phase, and the right side of phase shift indicator 868 can refer to the steady state phase. The x-axis can represent a duration and the y-axis can represent sensor values. Current sensor values can be plotted (not shown) and control line 866 can be generated. A slope value for control line 866 can be determined and a projected control line 867 can be generated. The projected control line crosses the upper fault detection limit 862, indicating that a fault will occur during the seasoning process. As such, a indication of a fault, such as an alert, can be generated. This allows the operator to be informed of approximately when the fault will occur, thus allowing the operator to take preventive corrective action.

FIG. 8G is another illustration of a fault detection control chart 807 generating a project control line, according to aspects of the present disclosure. Fault detection control chart 807 includes a set of fault detection limits (upper fault detection limit 872 and lower fault detection limit 874), phase shift indicator 878, control line 876, and projected control line 877. In this implementation, the left side of phase shift indicator 878 can refer to the seasoning phase, and the right side of phase shift indicator 878 can refer to the steady state phase. The x-axis can represent a duration and the y-axis can represent sensor values. Current sensor values can be plotted (not shown) and control line 876 can be generated. As shown, the control line 876 stayed within the fault detections limits 872 and 874 during the seasoning phase. A slope value for the control line 876 in the steady state phase can be determined and a projected control line 877 can be generated. The projected control line crosses the lower fault detection limit 874. As such, an indication of a fault, such as an alert, can be generated. This allows the operator to be informed of approximately when the fault will occur, thus allowing the operator to take preventive corrective action.

FIG. 8G is another illustration of a fault detection control chart 808 generating a fault due to a y-intercept value, according to aspects of the present disclosure. Fault detection control chart 808 includes a set of fault detection limits (upper fault detection limit 882 and lower fault detection limit 884), phase shift indicator 888, and control line 887. The x-axis can represent a duration and the y-axis can represent sensor values. Current sensor values can be plotted (not shown) and control line 886 can be generated. As shown, the control line 886 has a y-intercept outside of the fault detection limits. As such, an indication of a fault, such as an alert, can be generated. This allows the operator to be informed that a fault occurred at the start of the seasoning phase, thus allowing the operator to take preventive corrective action.

Corrective action module 117 can receive user input (e.g., via a Graphical User Interface (GUI) displayed via the client device 110) of an indication associated with manufacturing equipment 124. In some implementations, the corrective action module 117 receives input data from fault detection module 115 and/or chart generator 116, determines a corrective action based on the input data, and causes the corrective action to be implemented. For example, responsive to receiving an indication that sensor data satisfied a threshold criterion (e.g., exceeded or fell below a fault detection limit), the correction action module 116 can perform one or more corrective action (e.g., increase power, decrease flowrate, etc.). The corrective actions can be stored in a fault pattern library on data store 140. In some implementations, the corrective action module 117 receives an indication of a corrective action from the predictive system 160 and causes the corrective action to be implemented. Each client device 110 can include an operating system that allows users to one or more of generate, view, or edit data (e.g., indication associated with manufacturing equipment 124, corrective actions associated with manufacturing equipment 124, etc.).

Although shown as module of client device 110, each module 111-117 can be included in one or more other computing devices, such as a rackmount server, a router computer, a server computer, a personal computer, a mainframe computer, a laptop computer, a tablet computer, a desktop computer, a GPU, an ASIC, etc. Each module 111-117 can execute instructions to perform any one or more of the methodologies and/or implementations described herein. The instructions can be stored on a computer readable storage medium, which can include the main memory, static memory, secondary storage and/or processing device (during execution of the instructions).

Data store 140 can be a memory (e.g., random access memory), a drive (e.g., a hard drive, a flash drive), a database system, or another type of component or device capable of storing data. Data store 140 can include multiple storage components (e.g., multiple drives or multiple databases) that can span multiple computing devices (e.g., multiple server computers). The data store 140 can store data associated with processing a substrate at manufacturing equipment 124. For example, data store 140 can store data collected by sensors 126 at manufacturing equipment 124 before, during, or after a substrate process (referred to as process data). Process data can refer to historical process data (e.g., process data generated for a prior substrate processed at the manufacturing system) and/or current process data (e.g., process data generated for a current substrate processed at the manufacturing system). Data store can also store spectral data or non-spectral data associated with a portion of a substrate processed at manufacturing equipment 124. Spectral data can include historical spectral data and/or current spectral data.

Data store 140 can also store contextual data associated with one or more substrates processed at the manufacturing system. Contextual data can include a recipe name, recipe step number, preventive maintenance indicator, operator, etc. Contextual data can refer to historical contextual data (e.g., contextual data associated with a prior process performed for a prior substrate) and/or current process data (e.g., contextual data associated with current process or a future process to be performed for a prior substrate). The contextual data can further include identify sensors that are associated with a particular sub-system of a process chamber.

Data store 140 can also store task data. Task data can include one or more sets of operations to be performed for the substrate during a deposition process and can include one or more settings associated with each operation. For example, task data for a deposition process can include a temperature setting for a process chamber, a pressure setting for a process chamber, a flow rate setting for a precursor for a material of a film deposited on a substrate, etc. In another example, task data can include controlling pressure at a defined pressure point for the flow value. Task data can refer to historical task data (e.g., task data associated with a prior process performed for a prior substrate) and/or current task data (e.g., task data associated with current process or a future process to be performed for a substrate).

In some implementations, data store 140 can store statistics data. Statistics data can include statistics representative of the raw data, generated by SSM 112, e.g., mean data (average), range data, standard deviation data, maximum and minimum data, median data, mode data, etc. Mean data can include a measured averages of two or more values. For example, mean data can be used to determine the average heater temperature, the process chamber pressure, the average flowrate of a gas, etc., during a step(s), a specific time duration, an entire process recipe, etc. Range data can include the middle observation in a set of data (e.g., a median temperature during a step). Range data can include the difference between a maximum value and a minimum value of a set of values (e.g. the range of the heater pressure during a process recipe). The standard deviation is measure of the amount of variation or dispersion of a set of values.

In some implementations, data store 140 can store sensor group data. Sensor group data can include data identifying to which group a sensor is assigned. For example, a first set of sensors or arrays can be assigned (by grouping module 113) to the setpoint group, a second set of sensors or arrays can be assigned to the tool-life dependent group, etc. In some implementations, the sensor group data can include metadata that is related to each particular sensor. In some implementations, the sensor group data can include a data structure, such as a data table, which stores records, where each record include a sensor identifier and a group identifier.

In some implementations, data store 140 can be configured to store data that is not accessible to a user of the manufacturing system. For example, process data, spectral data, contextual data, etc. obtained for a substrate being processed at the manufacturing system is not accessible to a user (e.g., an operator) of the manufacturing system. In some implementations, all data stored at data store 140 can be inaccessible by the user of the manufacturing system. In other or similar implementations, a portion of data stored at data store 140 can be inaccessible by the user while another portion of data stored at data store 140 can be accessible by the user. In some implementations, one or more portions of data stored at data store 140 can be encrypted using an encryption mechanism that is unknown to the user (e.g., data is encrypted using a private encryption key). In other or similar implementations, data store 140 can include multiple data stores where data that is inaccessible to the user is stored in one or more first data stores and data that is accessible to the user is stored in one or more second data stores.

In some implementations, data store 140 can be configured to store data associated with known fault patterns. A fault pattern can be a one or more values (e.g., a vector, a scalar, etc.) associated with one or more issues or failures associated with a process chamber sub-system. In some implementations, a fault pattern can be associated with a corrective action. For example, a fault pattern can include parameter adjustment steps to correct the issue or failure indicated by the fault pattern. For example, the predictive system or the corrective action module can compare a determined fault pattern (determined from data obtained from of one or more sensors of a sensor cluster) to a library of known fault patterns to determine the type of failure experienced by a sub-system, the cause of the failure, the recommended corrective action to correct the fault, and so forth.

The client device 110, manufacturing equipment 124, sensors 126, predictive system 160, and data store 140 can be coupled to each other via a network 130. In some implementations, network 130 is a public network that provides client device 110 with access to predictive system 160, data store 140, manufacturing equipment 124 (not shown) and other publicly available computing devices. In some implementations, network 130 is a private network that provides client device 110 access to manufacturing equipment 124, data store 140, predictive system 160, and other privately available computing devices. Network 130 can include one or more wide area networks (WANs), local area networks (LANs), wired networks (e.g., Ethernet network), wireless networks (e.g., an 802.11 network or a Wi-Fi network), cellular networks (e.g., a Long-Term Evolution (LTE) network), routers, hubs, switches, server computers, cloud computing networks, and/or a combination thereof

In implementations, a “user” can be represented as a single individual. However, other implementations of the disclosure encompass a “user” being an entity controlled by a plurality of users and/or an automated source. For example, a set of individual users federated as a group of administrators can be considered a “user.”

FIG. 2 is a top schematic view of an example manufacturing system 200, according to aspects of the present disclosure. Manufacturing system 200 can perform one or more processes on a substrate 202. Substrate 202 can be any suitably rigid, fixed-dimension, planar article, such as, e.g., a silicon-containing disc or wafer, a patterned wafer, a glass plate, or the like, suitable for fabricating electronic devices or circuit components thereon.

Manufacturing system 200 can include a process tool 204 and a factory interface 206 coupled to process tool 204. Process tool 204 can include a housing 208 having a transfer chamber 210 therein. Transfer chamber 210 can include one or more process chambers (also referred to as processing chambers) 214, 216, 218 disposed therearound and coupled thereto. Process chambers 214, 216, 218 can be coupled to transfer chamber 210 through respective ports, such as slit valves or the like. Transfer chamber 210 can also include a transfer chamber robot 212 configured to transfer substrate 202 between process chambers 214, 216, 218, load lock 220, etc. Transfer chamber robot 212 can include one or multiple arms where each arm includes one or more end effectors at the end of each arm. The end effector can be configured to handle particular objects, such as wafers, sensor discs, sensor tools, etc.

Process chambers 214, 216, 218 can be adapted to carry out any number of processes on substrates 202. A same or different substrate process can take place in each processing chamber 214, 216, 218. A substrate process can include atomic layer deposition (ALD), physical vapor deposition (PVD), chemical vapor deposition (CVD), etching, annealing, curing, pre-cleaning, metal or metal oxide removal, or the like. Other processes can be carried out on substrates therein. Process chambers 214, 216, 218 can each include one or more sensors configured to capture data for substrate 202 before, after, or during a substrate process. For example, the one or more sensors can be configured to capture spectral data and/or non-spectral data for a portion of substrate 202 during a substrate process. In other or similar implementations, the one or more sensors can be configured to capture data associated with the environment within process chamber 214, 216, 218 before, after, or during the substrate process. For example, the one or more sensors can be configured to capture data associated with a temperature, a pressure, a gas concentration, etc. of the environment within process chamber 214, 216, 218 during the substrate process.

In some implementations, metrology equipment (not shown) can be located within the process tool. In other implementations, metrology equipment (not shown) can be located within one or more process chambers 214, 216, 218. In some implementations, the substrate can be placed onto metrology equipment using transfer chamber robot 212. In other implementations, the metrology equipment can be part of the substrate support assembly (not shown). Metrology equipment can provide metrology data associated with substrates processed by manufacturing equipment 124. The metrology data can include a value of film property data (e.g., wafer spatial film properties), dimensions (e.g., thickness, height, etc.), dielectric constant, dopant concentration, density, defects, etc. In some implementations, the metrology data can further include a value of one or more surface profile property data (e.g., an etch rate, an etch rate uniformity, a critical dimension of one or more features included on a surface of the substrate, a critical dimension uniformity across the surface of the substrate, an edge placement error, etc.). The metrology data can be of a finished or semi-finished product. The metrology data can be different for each substrate. Metrology data can be generated using, for example, reflectometry techniques, ellipsometry techniques, TEM techniques, and so forth.

A load lock 220 can also be coupled to housing 208 and transfer chamber 210. Load lock 220 can be configured to interface with, and be coupled to, transfer chamber 210 on one side and factory interface 206. Load lock 220 can have an environmentally-controlled atmosphere that can be changed from a vacuum environment (wherein substrates can be transferred to and from transfer chamber 210) to an at or near atmospheric-pressure inert-gas environment (wherein substrates can be transferred to and from factory interface 206) in some implementations. Factory interface 206 can be any suitable enclosure, such as, e.g., an Equipment Front End Module (EFEM). Factory interface 206 can be configured to receive substrates 202 from substrate carriers 222 (e.g., Front Opening Unified Pods (FOUPs)) docked at various load ports 224 of factory interface 206. A factory interface robot 226 (shown dotted) can be configured to transfer substrates 202 between carriers (also referred to as containers) 222 and load lock 220. Carriers 222 can be a substrate storage carrier or a replacement part storage carrier.

Manufacturing system 200 can also be connected to a client device (e.g., client device 110, not shown) that is configured to provide information regarding manufacturing system 200 to a user (e.g., an operator). In some implementations, the client device can provide information to a user of manufacturing system 200 via one or more graphical user interfaces (GUIs). For example, the client device can provide information regarding a target thickness profile for a film to be deposited on a surface of a substrate 202 during a deposition process performed at a process chamber 214, 216, 218 via a GUI. The client device can also provide information regarding anomaly detection and fault classification, in accordance with implementations described herein.

Manufacturing system 200 can also include a system controller 228. System controller 228 can be and/or include a computing device such as a personal computer, a server computer, a programmable logic controller (PLC), a microcontroller, and so on. System controller 228 can include one or more processing devices, which can be general-purpose processing devices such as a microprocessor, central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device can also be one or more special-purpose processing devices such as an application specific integrated circuit (ASIC), a field programmable gate array (FPGA), a digital signal processor (DSP), network processor, or the like. System controller 228 can include a data storage device (e.g., one or more disk drives and/or solid state drives), a main memory, a static memory, a network interface, and/or other components. System controller 228 can execute instructions to perform any one or more of the methodologies and/or implementations described herein. In some implementations, system controller 228 can execute instructions to perform one or more operations at manufacturing system 200 in accordance with a process recipe. The instructions can be stored on a computer readable storage medium, which can include the main memory, static memory, secondary storage and/or processing device (during execution of the instructions).

System controller 228 can receive data from sensors (e.g., sensors 126, now shown) included on or within various portions of manufacturing system 200 (e.g., processing chambers 214, 216, 218, transfer chamber 210, load lock 220, etc.). In some implementations, data received by the system controller 228 can include spectral data and/or non-spectral data for a portion of substrate 202. In other or similar implementations, data received by the system controller 228 can include data associated with processing substrate 202 at processing chamber 214, 216, 218, as described previously. For purposes of the present description, system controller 228 is described as receiving data from sensors included within process chambers 214, 216, 218. However, system controller 228 can receive data from any portion of manufacturing system 200 and can use data received from the portion in accordance with implementations described herein. In an illustrative example, system controller 228 can receive data from one or more sensors for process chamber 214, 216, 218 before, after, or during a substrate process at the process chamber 214, 216, 218. Data received from sensors of the various portions of manufacturing system 200 can be stored in a data store 250. Data store 250 can be included as a component within system controller 228 or can be a separate component from system controller 228. In some implementations, data store 250 can be data store 140 described with respect to FIG. 1.

FIG. 3 depicts an illustrative predictive architecture 300, according to aspects of the present disclosure. In some implementations, predictive architecture 300 include predictive system 160, network 130, and data store 310 (which can be similar to the same as data store 140). In some implementations, predictive system 160 can use a model (e.g., model 190) to group two or more sensor based on, for example, sensor statistics data. For example, model 190 can received sensor statistics data as input, and generate, as output, sensor cluster data. In some implementations, predictive system 160 can include predictive server 112, server machines 170 and 180, and predictive server 195. The predictive server 160, server machine 170, server machine 180, and predictive server 195 can each include one or more computing devices such as a rackmount server, a router computer, a server computer, a personal computer, a mainframe computer, a laptop computer, a tablet computer, a desktop computer, Graphics Processing Unit (GPU), accelerator Application-Specific Integrated Circuit (ASIC) (e.g., Tensor Processing Unit (TPU)), etc.

Server machine 170 includes a training set generator 172 that is capable of generating training data sets (e.g., a set of data inputs and a set of target outputs) to train, validate, and/or test a machine-learning model 190. Machine-learning model 190 can be any algorithmic model capable of learning from data. In some implementations, machine-learning model 190 can be a predictive model. In some implementations, the data set generator 172 can partition the training data into a training set, a validating set, and a testing set, which can be stored, as part of the training statistics 312, in the training data store 310. Training statistics 312 which can be accessible to the computing device predictive system 160 directly or via network 130. In some implementations, the predictive system 160 generates multiple sets of training data.

Server machine 180 can include a training engine 182, a validation engine 184, a selection engine 185, and/or a testing engine 186. An engine can refer to hardware (e.g., circuitry, dedicated logic, programmable logic, microcode, processing device, etc.), software (such as instructions run on a processing device, a general-purpose computer system, or a dedicated machine), firmware, microcode, or a combination thereof. Training engine 182 can be capable of training one or more machine-learning model 190. Machine-learning model 190 can refer to the model artifact that is created by the training engine 182 using the training data (also referred to herein as a training set) that includes training inputs and corresponding target outputs (correct answers for respective training inputs). The training engine 182 can find patterns in the training data that map the training input to the target output (the answer to be predicted), and provide the machine-learning model 190 that captures these patterns. The machine-learning model 190 can use one or more of a statistical modelling, support vector machine (SVM), Radial Basis Function (RBF), clustering, supervised machine-learning, semi-supervised machine-learning, unsupervised machine-learning, k-nearest neighbor algorithm (k-NN), linear regression, random forest, neural network (e.g., artificial neural network), etc.

One type of machine learning model that can be used to perform some or all of the above tasks is an artificial neural network, such as a deep neural network. Artificial neural networks generally include a feature representation component with a classifier or regression layers that map features to a desired output space. A convolutional neural network (CNN), for example, hosts multiple layers of convolutional filters. Pooling is performed, and non-linearities can be addressed, at lower layers, on top of which a multi-layer perceptron is commonly appended, mapping top layer features extracted by the convolutional layers to decisions (e.g. classification outputs). Deep learning is a class of machine learning algorithms that use a cascade of multiple layers of nonlinear processing units for feature extraction and transformation. Each successive layer uses the output from the previous layer as input. Deep neural networks can learn in a supervised (e.g., classification) and/or unsupervised (e.g., pattern analysis) manner. Deep neural networks include a hierarchy of layers, where the different layers learn different levels of representations that correspond to different levels of abstraction. In deep learning, each level learns to transform its input data into a slightly more abstract and composite representation. In a plasma process tuning, for example, the raw input can be process result profiles (e.g., thickness profiles indicative of one or more thickness values across a surface of a substrate); the second layer can compose feature data associated with a status of one or more zones of controlled elements of a plasma process system (e.g., orientation of zones, plasma exposure duration, etc.); the third layer can include a starting recipe (e.g., a recipe used as a starting point for determining an updated process recipe the process a substrate to generate a process result the meets threshold criteria). Notably, a deep learning process can learn which features to optimally place in which level on its own. The “deep” in “deep learning” refers to the number of layers through which the data is transformed. More precisely, deep learning systems have a substantial credit assignment path (CAP) depth. The CAP is the chain of transformations from input to output. CAPs describe potentially causal connections between input and output. For a feedforward neural network, the depth of the CAPs can be that of the network and can be the number of hidden layers plus one. For recurrent neural networks, in which a signal can propagate through a layer more than once, the CAP depth is potentially unlimited.

In one implementation, one or more machine learning model is a recurrent neural network (RNN). An RNN is a type of neural network that includes a memory to enable the neural network to capture temporal dependencies. An RNN is able to learn input-output mappings that depend on both a current input and past inputs. The RNN will address past and future flow rate measurements and make predictions based on this continuous metrology information. RNNs can be trained using a training dataset to generate a fixed number of outputs (e.g., to determine a set of substrate processing rates, determine modification to a substrate process recipe). One type of RNN that can be used is a long short term memory (LSTM) neural network.

Training of a neural network can be achieved in a supervised learning manner, which involves feeding a training dataset consisting of labeled inputs through the network, observing its outputs, defining an error (by measuring the difference between the outputs and the label values), and using techniques such as deep gradient descent and backpropagation to tune the weights of the network across all its layers and nodes such that the error is minimized. In many applications, repeating this process across the many labeled inputs in the training dataset yields a network that can produce correct output when presented with inputs that are different than the ones present in the training dataset.

A training dataset containing hundreds, thousands, tens of thousands, hundreds of thousands or more sensor data and/or process result data (e.g., metrology data such as one or more thickness profiles associated with the sensor data) can be used to form a training dataset.

To effectuate training, processing logic can input the training dataset(s) into one or more untrained machine learning models. Prior to inputting a first input into a machine learning model, the machine learning model can be initialized. Processing logic trains the untrained machine learning model(s) based on the training dataset(s) to generate one or more trained machine learning models that perform various operations as set forth above. Training can be performed by inputting one or more of the sensor data into the machine learning model one at a time.

The machine learning model processes the input to generate an output. An artificial neural network includes an input layer that consists of values in a data point. The next layer is called a hidden layer, and nodes at the hidden layer each receive one or more of the input values. Each node contains parameters (e.g., weights) to apply to the input values. Each node therefore essentially inputs the input values into a multivariate function (e.g., a non-linear mathematical transformation) to produce an output value. A next layer can be another hidden layer or an output layer. In either case, the nodes at the next layer receive the output values from the nodes at the previous layer, and each node applies weights to those values and then generates its own output value. This can be performed at each layer. A final layer is the output layer, where there is one node for each class, prediction and/or output that the machine learning model can produce.

Accordingly, the output can include one or more predictions or inferences. In some implementations, an output prediction or inference can include one or more predictions of sensor group classifications, sensor rankings, etc. In some implementations, an output prediction or inference can include one or more predictions of anomaly data, fault data, fault detection limits, etc. Processing logic determines an error (i.e., a classification error) based on the differences between the output (e.g., predictions or inferences) of the machine learning model and target labels associated with the input training data. Processing logic adjusts weights of one or more nodes in the machine learning model based on the error. An error term or delta can be determined for each node in the artificial neural network. Based on this error, the artificial neural network adjusts one or more of its parameters for one or more of its nodes (the weights for one or more inputs of a node). Parameters can be updated in a back propagation manner, such that nodes at a highest layer are updated first, followed by nodes at a next layer, and so on. An artificial neural network contains multiple layers of “neurons”, where each layer receives as input values from neurons at a previous layer. The parameters for each neuron include weights associated with the values that are received from each of the neurons at a previous layer. Accordingly, adjusting the parameters can include adjusting the weights assigned to each of the inputs for one or more neurons at one or more layers in the artificial neural network.

After one or more rounds of training, processing logic can determine whether a stopping criterion has been met. A stopping criterion can be a target level of accuracy, a target number of processed images from the training dataset, a target amount of change to parameters over one or more previous data points, a combination thereof and/or other criteria. In one implementation, the stopping criteria is met when at least a minimum number of data points have been processed and at least a threshold accuracy is achieved. The threshold accuracy can be, for example, 70%, 80% or 90% accuracy. In one implementation, the stopping criterion is met if accuracy of the machine learning model has stopped improving. If the stopping criterion has not been met, further training is performed. If the stopping criterion has been met, training can be complete. Once the machine learning model is trained, a reserved portion of the training dataset can be used to test the model.

Once one or more trained machine learning models 190 are generated, they can be stored in predictive server 195 as predictive component 197 or as a component of predictive component 197.

The validation engine 184 can be capable of validating machine-learning model 190 using a corresponding set of features of a validation set from training set generator 172. Once the model parameters have been optimized, model validation can be performed to determine whether the model has improved and to determine a current accuracy of the deep learning model. The validation engine 184 can determine an accuracy of machine-learning model 190 based on the corresponding sets of features of the validation set. The validation engine 184 can discard a trained machine-learning model 190 that has an accuracy that does not meet a threshold accuracy. In some implementations, the selection engine 185 can be capable of selecting a trained machine-learning model 190 that has an accuracy that meets a threshold accuracy. In some implementations, the selection engine 185 can be capable of selecting the trained machine-learning model 190 that has the highest accuracy of the trained machine-learning models 190.

The testing engine 186 can be capable of testing a trained machine-learning model 190 using a corresponding set of features of a testing set from data set generator 172. For example, a first trained machine-learning model 190 that was trained using a first set of features of the training set can be tested using the first set of features of the testing set. The testing engine 186 can determine a trained machine-learning model 190 that has the highest accuracy of all of the trained machine-learning models based on the testing sets.

As described in detail below, predictive server 195 includes a predictive component 197 that is capable of providing data indicative of sensor groupings or rankings, and running trained machine-learning model 190 on data items such as sensor data, statistics data, etc. input to obtain one or more outputs. The predictive server 195 can further provide fault detection data and/or anomaly detection data. This will be explained in further detail below.

It should be noted that in some other implementations, the functions of server machines 170 and 180, as well as predictive server 195, can be provided by a fewer number of machines. For example, in some implementations, server machines 170 and 180 can be integrated into a single machine, while in some other or similar implementations, server machines 170 and 180, as well as predictive server 195, can be integrated into a single machine.

In general, functions described in one implementation as being performed by server machine 170, server machine 180, and/or predictive server 195 can also be performed on client device 110. In addition, the functionality attributed to a particular component can be performed by different or multiple components operating together.

In some implementations, a manufacturing system can include more than one process chambers. For example, example manufacturing system 200 of FIG. 2 illustrates multiple process chambers 214, 216, 218. It should be noted that, in some implementations, data obtained to train the machine-learning model 190 and data collected to be provided as input to the machine-learning model can be associated with the same process chamber of the manufacturing system. In other or similar implementations, data obtained to train the machine-learning model and data collected to be provided as input to the machine-learning model can be associated with different process chambers of the manufacturing system. In other or similar implementations, data obtained to train the machine-learning model can be associated with a process chamber of a first manufacturing system and data collected to be provide as input to the machine-learning model can be associated with a process chamber of a second manufacturing system.

FIG. 9 is a flow chart of a method 900 for generating sensor group data, according to aspects of the present disclosure. Method 900 is performed by processing logic that can include hardware (circuitry, dedicated logic, etc.), software (such as is run on a general-purpose computer system or a dedicated machine), firmware, or some combination thereof. In one implementation, method 900 can be performed by a computer system, such as computer system architecture 100 of FIG. 1. In other or similar implementations, one or more operations of method 900 can be performed by one or more other machines not depicted in the figures. In some aspects, one or more operations of method 900 can be performed by client device 110, server machine 170, server machine 190, and/or predictive server 195. In some implementations, method 900 can be performed by grouping module 113 and can use a distributions algorithm to categorize sensors into one or more specific groups.

At operation 910, processing logic obtain output data related to a sensor. The sensor can be related to one or more process chambers of manufacturing equipment 124, one or more process chambers of multiple manufacturing equipments 124, etc. The data can be obtained from, for example, manufacturing equipment 124, data store 140, client device 110, etc.

At operation 920, processing logic generates a first distribution, based on the data, based on time. This first distribution can include a set of data points (e.g., output values) related to the sensor over time. In some implementation, the distribution can include a Gaussian distribution (which determines a mean value and one or more deviations from the mean value), a graph, etc.

At operation 930, processing logic generates a second distribution, based on the data, based on tool-life. Each distribution can include a set of data points (e.g., output values) over the tool-life. In some implementation, the distribution can include a Gaussian distribution, a graph, etc.

At operation 940, processing logic generates coefficients of variations based on both distributions. For example, the processing logic can calculate a coefficient of variation for each correlating sensor value.

At operation 950, the processing logic generates correlation coefficients based on both distributions. For example, the processing logic can calculate a correlation coefficient for each correlating sensor value. In an example, the correlation coefficient is a number between −1 and 1.

At operation 960, the processing logic determines whether the coefficients of variations (CV) are below a threshold value. The threshold value can be determined using experimentation, machine learning, user input, etc. Responsive to determining that the coefficients of variations are below a threshold value, the processing logic proceeds to operation 970A. Responsive to determining that the coefficients of variations are at or above a threshold value, the processing logic proceeds to operation 970B.

At operation 970A-B, the processing logic determines whether the correlation coefficients (CC) of one or more distributions satisfy a threshold criterion. For example, the processing logic can determine whether the correlation coefficients are with a predetermined value to the value 1. At operation 970A, responsive to the correlation coefficients satisfying the threshold criterion, the processing logic, at operation 980, categorizes the sensor as a setpoint sensor. Responsive to the correlation coefficients failing to satisfy the threshold criterion, the processing logic, at operation 995, categorizes the sensor as a variability sensor.

At operation 970B, responsive to the correlation coefficients of the tool life distribution satisfy the threshold criterion, the processing logic, at operation 990, categorizes the sensor as a tool-life sensor. Responsive to the correlation coefficients failing to satisfy the threshold criterion, the processing logic, at operation 995, categorizes the sensor as a variability sensor. It is noted that the thresholds associated with operation 970A and 970 can be the same or different.

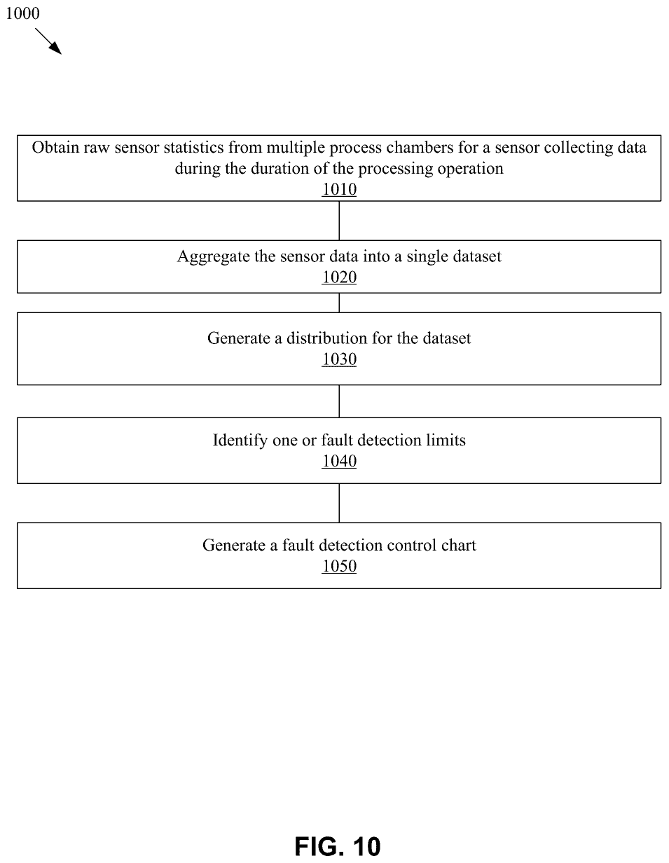

FIG. 10 is a flow chart of a method 1000 of fault detection based on aggregate statistics, according to aspects of the present disclosure. Method 1000 is performed by processing logic that can include hardware (circuitry, dedicated logic, etc.), software (such as is run on a general-purpose computer system or a dedicated machine), firmware, or some combination thereof. In one implementation, method 1000 can be performed by a computer system, such as computer system architecture 100 of FIG. 1. In other or similar implementations, one or more operations of method 1000 can be performed by one or more other machines not depicted in the figures. In some aspects, one or more operations of method 1000 can be performed by client device 110, server machine 170, server machine 180, and/or predictive server 195.

At operation 1010, processing logic obtains raw sensor statistics from multiple process chambers for a sensor (e.g., sensors 126) collecting data during the duration of the processing operation(s) (e.g., a process run). The set of sensors activated (or collecting data) during the processing operation(s) can be selected by the processing device based on the specifics of the processing operation(s). The raw sensor statistics can characterize a plurality of measurements associated with the activated (sampled) sensors. The statistics describing measurements collected by each or some of the sensors can include various parameters, such as a median, a mode, a variance, a standard deviation, a range, a maximum, a minimum, a skewness, or a kurtosis.

At operation 1020, the processing logic aggregates the sensor data into a single dataset. For example, the processing logic can combine the sensor data from each process chamber into a single dataset.

At operation 1030, the processing logic generates a distribution for the dataset. In some implementations, the processing logic generates a Gaussian distribution.

At operation 1040, the processing logic identifies one or fault detection limits. In one implementation, the fault detection limit can include the standard deviation thresholds of the Gaussian distribution.

At operation 1050, the processing logic generates a fault detection control chart. Fault detection control chart can be used for monitoring for faults during subsequent process runs. In some implementations, after a maintenance of one or more process chamber is complete, processing logic can obtain sensor data and plot the sensor data on the detection control chart in real or near-real time. Responsive to a sensor output value crossing a fault detection limit, the processing logic can indicate an alert, perform a corrective action, etc. In some implementations, processing logic can determine a control line associated with the sensor data, and determine a slope of the control line. In response to the slope value satisfying a threshold criterion (e.g., crossing a fault detection limit), the processing logic can indicate an alert, preform a corrective action, etc. In some implementations, processing logic can determine a y-intercept of the control line. In response to the y-intercept satisfying a threshold criterion (e.g., crossing a fault detection limit), the processing logic can indicate an alert, preform a corrective action, etc.

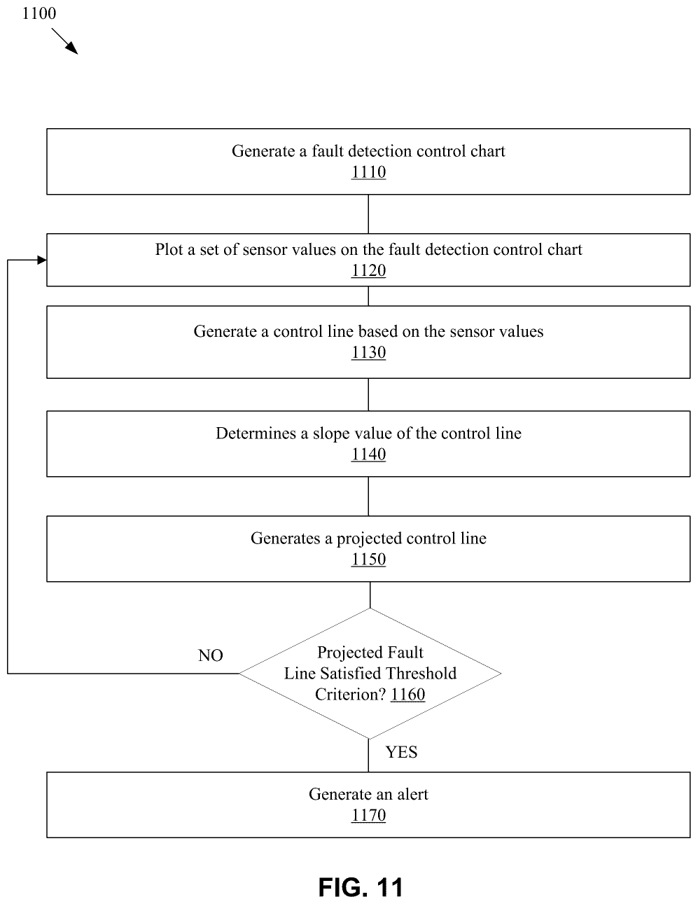

FIG. 11 is a flow chart of a method 1100 for determining a projected control line, according to aspects of the present disclosure. Method 1100 is performed by processing logic that can include hardware (circuitry, dedicated logic, etc.), software (such as is run on a general-purpose computer system or a dedicated machine), firmware, or some combination thereof. In one implementation, method 1100 can be performed by a computer system, such as computer system architecture 100 of FIG. 1. In other or similar implementations, one or more operations of method 1100 can be performed by one or more other machines not depicted in the figures. In some aspects, one or more operations of method 1100 can be performed by client device 110, server machine 170, server machine 180, and/or predictive server 195.

At operation 1110, processing logic generates a fault detection control chart. For example, processing logic can perform one or more operations of FIG. 9 to generate the fault detection control chart.

At operation 1120, processing logic plots a set of sensor values on the fault detection control chart. The sensor values can be related to one or more current process runs being performed in a process chamber. The sensor value can relate to one or more sensors.

At operation 1130, processing logic generates a control line based on the sensor values. In some implementations, the control line can be generated by determining a line of best fit of the sensor data, using any other method capable of determining a relationship between the sensor data, using predictive server 195, etc.

At operation 1140, processing logic determines a slope value of the control line. In some implementations, the slope can be determined using the equation y=m*x+b.

At operation 1150, processing logic generates a projected control line. In some implementations, the processing logic can generate the projected control line by extending the control line using the slope value. The projected control line can be extended for a predetermined duration. The projected control line can be re-graphed in predetermined intervals (e.g., for every five current data point plotted, for every current data point plotted, etc.).

At operation 1160, processing logic determines whether the projected fault line satisfies a threshold criterion (e.g., crosses a fault detection limit). In response to the projected control line crossing a fault detection limit, the processing logic proceeds to operation 1170 and generates an alert. Otherwise, the processing logic proceeds to operation 1120 to obtain additional sensor values and generate (at operation 1150) a new projected control line.

In some implementations, processing logic can set the triggers based on the slope value of the control line, as discussed above in relation to FIG. 8B. In response to the slope value satisfying a threshold criterion (e.g., the slope value of the control line being above or below a predetermined value, the processing logic can generate an alert.

In some implementations, the processing logic can determine a slope of the sensor data. The slope can be used to determine whether one or more sensors, a process chamber, a process chamber sub-system, etc. is experiencing a fault. In some implementations, the processing logic can compare the slope to one or more fault detection limits to determine whether a fault exists. For example, the processing logic can determine a slope of the sensor output values and compare the sensor slope to the slope of one or more of fault detection limits. Responsive to the sensor slope value having a difference from the fault detection limit that satisfied a threshold criterion (e.g., sensor slope value is greater than or less than the slope of the fault detection limit by a predetermined value, percentage, etc.), the processing logic can indicate a warning, perform a corrective action, etc.

In some implementations, the processing logic can update fault detection limits in response to determining that a value (e.g., a number of substrates processed in a process chamber since the last maintenance operation on the process chamber, a time value lapsing, etc.) satisfies a threshold criterion. In particular, the processing logic can track the duration of a production run. In response to determining that the duration of the production run satisfies a threshold criterion (e.g., the number of substrates processed satisfied a threshold value, the time elapsed since the start of the production run satisfied a threshold value, etc.), the processing logic can update (e.g., reset or set to a new value) the value(s) of the fault detention limit(s). In some implementations, the threshold criterion can reflect desired or scheduled maintenance operation(s). In one example, the fault detection limits can be reset to the values that were set at the start of the production run. In another example, the fault detection limits can be update to new values determined by fault detection module 115 or chart generator 116.

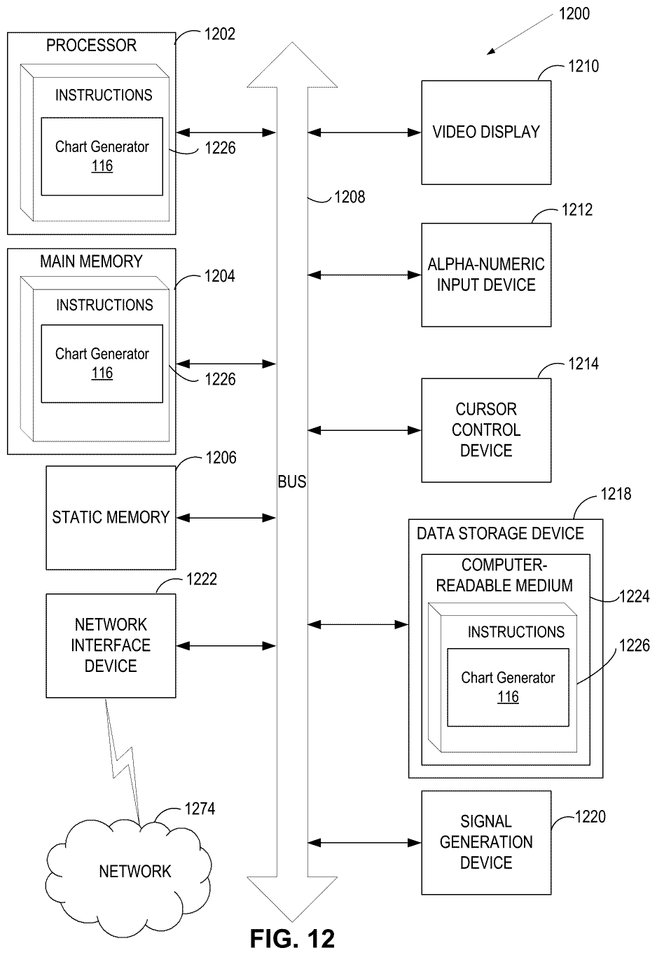

FIG. 12 is a block diagram illustrating a computer system 1200, according to certain implementations. In some implementations, computer system 1200 can be connected (e.g., via a network, such as a Local Area Network (LAN), an intranet, an extranet, or the Internet) to other computer systems. Computer system 1200 can operate in the capacity of a server or a client computer in a client-server environment, or as a peer computer in a peer-to-peer or distributed network environment. Computer system 1200 can be provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 1200 can include a processing device 1202, a volatile memory 1204 (e.g., Random Access Memory (RAM)), a non-volatile memory 1206 (e.g., Read-Only Memory (ROM) or Electrically-Erasable Programmable ROM (EEPROM)), and a data storage device 1216, which can communicate with each other via a bus 1208.

Processing device 1202 can be provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

Computer system 1200 can further include a network interface device 1222 (e.g., coupled to network 1274). Computer system 1200 also can include a video display unit 1210 (e.g., an LCD), an alphanumeric input device 1212 (e.g., a keyboard), a cursor control device 1214 (e.g., a mouse), and a signal generation device 1220.

In some implementations, data storage device 1216 can include a non-transitory computer-readable storage medium 1224 on which can store instructions 1226 encoding any one or more of the methods or functions described herein, including instructions encoding components of FIG. 1 (e.g., SCM 111, SSM 112, group module 113, ADM 114, FDM 115, chart generator 116, and corrective action module 116, etc.) and for implementing methods described herein.

Instructions 1226 can also reside, completely or partially, within volatile memory 1204 and/or within processing device 1202 during execution thereof by computer system 1200, hence, volatile memory 1204 and processing device 1202 can also constitute machine-readable storage media.

While computer-readable storage medium 1224 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

The methods, components, and features described herein can be implemented by discrete hardware components or can be integrated in the functionality of other hardware components such as ASICS, FPGAs, DSPs or similar devices. In addition, the methods, components, and features can be implemented by firmware modules or functional circuitry within hardware devices. Further, the methods, components, and features can be implemented in any combination of hardware devices and computer program components, or in computer programs.

Unless specifically stated otherwise, terms such as “receiving,” “performing,” “providing,” “obtaining,” “causing,” “accessing,” “determining,” “adding,” “using,” “training,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. Also, the terms “first,” “second,” “third,” “fourth,” etc. as used herein are meant as labels to distinguish among different elements and can not have an ordinal meaning according to their numerical designation.

Examples described herein also relate to an apparatus for performing the methods described herein. This apparatus can be specially constructed for performing the methods described herein, or it can include a general purpose computer system selectively programmed by a computer program stored in the computer system. Such a computer program can be stored in a computer-readable tangible storage medium.

The methods and illustrative examples described herein are not inherently related to any particular computer or other apparatus. Various general purpose systems can be used in accordance with the teachings described herein, or it can prove convenient to construct more specialized apparatus to perform methods described herein and/or each of their individual functions, routines, subroutines, or operations. Examples of the structure for a variety of these systems are set forth in the description above.

The above description is intended to be illustrative, and not restrictive. Although the present disclosure has been described with references to specific illustrative examples and implementations, it will be recognized that the present disclosure is not limited to the examples and implementations described. The scope of the disclosure should be determined with reference to the following claims, along with the full scope of equivalents to which the claims are entitled.

1. A method, comprising:
obtaining, by a processing device, current sensor data associated with a sensor of a substrate manufacturing system;
determining a slope value associated with the current sensor data;
responsive to determining that the slope value satisfied a threshold criterion associated with a fault detection limit, performing at least one of generating an alert or performing a corrective action.

2. The method of claim 1, wherein a slope of the fault detection limit comprises a first value for a first duration of a production run and a second value for a second duration of the production run.

3. The method of claim 1, further comprising:
determining a control line based on the current sensor data;
determining a projected control line based on the control line and the slope value; and
displaying the projected control line on a graphical user interface.

4. The method of claim 1, determining that a y-intercept value associated with the control line satisfies a further threshold criterion associated with the fault detection limit; and
responsive to determining that the y-intercept value satisfied a further threshold criterion associated with the fault detection limit, performing at least one of generating the alert or performing the corrective action.

5. The method of claim 1, wherein the slope value is updated in response to receiving additional sensor data.

6. The method of claim 1, further comprising:
obtaining, a plurality of datasets each comprising sensor output data from a respective sensor of a plurality of sensors each associated with a corresponding process chamber of a plurality of process chambers;
combining the plurality of datasets into an aggregate dataset;
generating a distribution of the aggregate dataset; and
identifying the fault detection limit based on a deviation value generated from the distribution.

7. The method of claim 6, further comprising:
obtaining output data associated with a sensor of the plurality of sensors;
generating a first distribution based on the output data and a set of time values;
generating a second distribution based on the output data and a set of tool-life values;
generating a set of coefficients of variations based on the first distribution and the second distribution;
generating a set of correlation coefficients based on the first distribution and the second distribution; and
responsive to the set of coefficients of variations satisfying a first threshold criterion, and the correlation coefficients satisfying a second threshold criterion, assigning the sensor to a group.

8. The method of claim 7, wherein the group reflects sensors whose output values do not drift over time.

9. The method of claim 7, further comprising:
responsive to the set of coefficients of variations failing to satisfy the first threshold criterion, and the set of correlation coefficients satisfying the second threshold criterion, assigning the sensor to a tool-life group reflecting sensors whose output values drift with time.

10. The method of claim 7, further comprising:
responsive to the set of correlation coefficients failing to satisfy the second threshold criterion, assigning the sensor to a variability group reflecting sensors which generate asymmetric data.

11. The method of claim 7, wherein at least one of the first distribution or the second distribution is a Gaussian distribution.

12. The method of claim 7, further comprising:
displaying, via a graphical user interface, a health index associated with a set of related sensors, assigned to the group, from a plurality of process chambers.

13. The method of claim 1, further comprising:
responsive to determining that a duration of a production run satisfies a further threshold criterion, updating a value associated with the fault detection limit.

14. An electronic device manufacturing system, comprising:
a memory device; and
a processing device, operatively coupled to the memory device, to perform operations comprising:
obtaining current sensor data associated with a sensor of the manufacturing system;
determining a slope value associated with the current sensor data;
responsive to determining that the slope value satisfied a threshold criterion associated with a fault detection limit, performing at least one of generating an alert or performing a corrective action.

15. The system of claim 14, wherein a slope of the fault detection limit comprises a first value for a first duration of a production run and a second value for a second duration of the production run.

16. The system of claim 14, further comprising:
determining a control line based on the current sensor data;
determining a projected control line based on the control line and the slop value; and
displaying the projected control line on a graphical user interface.

17. The system of claim 14, determining that a y-intercept value associated with the control line satisfies a further threshold criterion associated with the fault detection limit; and
responsive to determining that the y-intercept value satisfied a further threshold criterion associated with the fault detection limit, performing at least one of generating the alert or performing the corrective action.

18. The system of claim 14, wherein the slope value is updated in response to receiving additional sensor data.

19. The system of claim 14, wherein the operations further comprise:
obtaining a plurality of datasets each comprising sensor output data from a respective sensor of a plurality of sensors each associated with a corresponding process chamber of a plurality of process chambers;
combining the plurality of datasets into an aggregate dataset;
generating a distribution of the aggregate dataset; and
identifying the fault detection limit based on a deviation value generated from the distribution.

20. A non-transitory computer-readable storage medium comprising instructions that, when executed by a processing device operatively coupled to a memory, performs operations comprising:
obtaining a plurality of datasets each comprising sensor output data from a respective sensor of a plurality of sensors each associated with a corresponding process chamber of a plurality of process chambers;
combining the plurality of datasets into an aggregate dataset;
generating a distribution of the aggregate dataset; and
identifying the fault detection limit based on a deviation value generated from the distribution.

21. The non-transitory computer-readable storage medium of claim 20, wherein a slope of the fault detection limit comprises a first value for a first duration of a production run and a second value for a second duration of the production run.
